(19) United States
(12) Patent Application Publication
(10) Pub. No.: US 2026/0141954 A1
(43) Pub. Date: May 21, 2026

(54) METHOD OF OPERATING NONVOLATILE MEMORY DEVICE AND NONVOLATILE MEMORY DEVICE

(71) Applicant: SAMSUNG ELECTRONICS CO., LTD., Suwon-si (KR)

(72) Inventors: Kyeore HAN, Suwon-si (KR); Kwangho CHOI, Suwon-si (KR)

(73) Assignee: SAMSUNG ELECTRONICS CO., LTD., Suwon-si (KR)

(21) Appl. No.: 19/271,272

(22) Filed: Jul. 16, 2025

(30) Foreign Application Priority Data
Nov. 19, 2024 (KR) 10-2024-0165010

(51) Int. Cl. G11C 16/10; G11C 16/04; G11C 16/08; G11C 16/14; G11C 16/34; H10B 43/27; H10B 43/35

(52) U.S. Cl. CPC G11C 16/10; G11C 16/0483; G11C 16/08; G11C 16/3459; G11C 16/14; H10B 43/27; H10B 43/35

(57) ABSTRACT

A method of operating a nonvolatile memory device is provided. The method includes: performing a program operation on a selected word-line of a plurality of cell strings during a program execution period of a program loop by applying a program voltage to the selected word-line; and performing a program verification operation during a program verification period of the program loop by applying a program verification voltage to the selected word-line and by applying a first verification pass voltage to a first zone of unselected word-lines among and a second verification pass voltage to a second zone of the unselected word-lines. A voltage level of the second verification pass voltage is lower than a voltage level of the first verification pass voltage.

### CROSS-REFERENCE TO RELATED APPLICATION

This application claims priority under to Korean Patent Application No. 10-2024-0165010, filed on Nov. 19, 2024, in the Korean Intellectual Property Office, the disclosure of which is incorporated herein by reference in its entirety.

### BACKGROUND

The present disclosure relates to semiconductor memory devices, and more particularly to a method of operating a nonvolatile memory device and a nonvolatile memory device performing the same.

Semiconductor memory devices for storing data include volatile memory devices and nonvolatile memory devices. Volatile memory devices, such as dynamic random access memory (DRAM) devices, are typically configured to store data by charging or discharging capacitors in memory cells, and lose the stored data when power is off. Nonvolatile memory devices, such as flash memory devices, may maintain stored data even when power is interrupted. Volatile memory devices are widely used as main memories of various apparatuses, while nonvolatile memory devices are widely used for storing program codes and/or data in various electronic devices, such as computers, mobile devices, etc.

Recently, nonvolatile memory devices of three-dimensional structure such as a vertical NAND memory devices have been developed to increase integration degree and memory capacity of the nonvolatile memory devices. Along with increases in the integration degree and memory capacity, sensed current may be degraded as operating temperature of the nonvolatile memory device decreases.

### SUMMARY

One or more example embodiments provide a method of operating a nonvolatile memory device, capable of securing reliability of a program verification operating when an operating temperature of the nonvolatile memory device decreases.

One or more example embodiments provide a nonvolatile memory device capable of securing reliability of a program verification operating when an operating temperature of the nonvolatile memory device decreases.

According to as aspect of an example embodiment, a method of operating a nonvolatile memory device that includes at least one memory block, the at least one memory block including a plurality of cell strings, each of the plurality of cell strings including a string selection transistor, a plurality of memory cells and a ground selection transistor which are connected in series in a vertical direction between each of a plurality of bit-lines and a common source line in or on a substrate, is provided. The method includes: performing a program operation on a selected word-line of the plurality of cell strings during a program execution period of a program loop by applying a program voltage to the selected word-line; and performing a program verification operation during a program verification period of the program loop by applying a program verification voltage to the selected word-line and by applying a first verification pass voltage to a first zone of unselected word-lines among of the plurality of cell strings and a second verification pass voltage to a second zone of the unselected word-lines. A voltage level of the second verification pass voltage is lower than a voltage level of the first verification pass voltage.

According to another aspect of an example embodiment, a nonvolatile memory device including: a memory cell array including at least one memory block, the at least one memory block including a plurality of cell strings, each of the plurality of cell strings including a string selection transistor, a plurality of memory cells and a ground selection transistor which are connected in series in a vertical direction between each of a plurality of bit-lines and a common source line in or on a substrate; a temperature sensor configured to sense an operating temperature of the nonvolatile memory device; and a control circuit configured to, based on a program command and an access address: perform a program operation on a selected word-line of the plurality of cell strings during a program execution period of a program loop by applying a program voltage to the selected word-line; and perform a program verification operation during a program verification period of the program loop by applying a program verification voltage to the selected word-line and by applying a first verification pass voltage to a first zone of unselected word-lines among of the plurality of cell strings and a second verification pass voltage to a second zone of the unselected word-lines. A voltage level of the second verification pass voltage is lower than a voltage level of the first verification pass voltage.

According to another aspect of an example embodiment a memory cell array including at least one memory block, the at least one memory block including a plurality of cell strings, each of the plurality of cell strings including a string selection transistor, a plurality of memory cells and a ground selection transistor which are connected in series in a vertical direction between a first bit-line and a common source line in or on a substrate; a page buffer coupled to the memory cell array through the first bit-line; a digital temperature sensor configured to generate a digital temperature code corresponding to an operating temperature of the nonvolatile memory device; and a control circuit configured to, based on a program command and an access address: perform a program operation on a selected word-line of the plurality of cell strings during a program execution period of a program loop by applying a program voltage to the selected word-line; perform a program verification operation during a program verification period of the program loop by applying a program verification voltage to the selected word-line and by applying a first verification pass voltage to a first zone of unselected word-lines among of the plurality of cell strings and a second verification pass voltage to a second zone of the unselected word-lines, the first zone including a first number of the unselected word-lines and the second zone including a second number of the unselected word-lines; and increase the first number and reducing the second number based on the digital temperature code indicating a decrease in the sensed operating temperature during the program verification operation to perform temperature compensation on a current provided to a sensing node of the page buffer through the first bit-line. A voltage level of the second verification pass voltage is lower than a voltage level of the first verification pass voltage.

A control circuit in a nonvolatile memory device according to one or more example embodiments may adjust a first number of unselected word-lines to which a first verification pass voltage is applied and a second number of unselected word-lines to which a second verification pass voltage, smaller than the first verification pass voltage, is applied based on an operating temperature of the nonvolatile memory device during a program verification operation. That is, the nonvolatile memory device may reduce the second number as the operating temperature decreases and thus, may prevent a sensed current provided to a sensing node of a page buffer from being degraded as the operating temperature decreases.

### BRIEF DESCRIPTION OF DRAWINGS

The above and other objects and features will be more clearly understood from the following description, taken in conjunction with the accompanying drawings.

FIG. 1 is a flow chart illustrating a method of operating a nonvolatile memory device according to example embodiments.

FIG. 2 is a flow chart illustrating an example of performing the program operation on the selected word-line in FIG. 1 according to example embodiments.

FIG. 3 is a flow chart illustrating an example of performing the program verification operation in FIG. 1 according to example embodiments.

FIG. 4 is a flow chart illustrating an example of adjusting the first number and the second number in in FIG. 3 according to example embodiments.

FIG. 5 is a timing diagram illustrating a method of operating a nonvolatile memory device according to example embodiments.

FIG. 6 is a block diagram illustrating a memory system according to example embodiments.

FIG. 7 is a block diagram illustrating an example of the memory controller in the memory system in FIG. 6 according to example embodiments.

FIG. 8 illustrates a connection example of the memory controller and the nonvolatile memory device in FIG. 6 according to example embodiments.

FIG. 9 is a block diagram illustrating an example of the nonvolatile memory device in the memory system of FIG. 6 according to example embodiments.

FIG. 10 schematically illustrates a structure of the nonvolatile memory device of FIG. 9 according to example embodiments.

FIG. 11 is a block diagram illustrating an example of the memory cell array in the nonvolatile memory device of FIG. 9 according to example embodiments.

FIG. 12 is a circuit diagram illustrating one of the memory blocks of FIG. 11 according to example embodiments.

FIG. 13 illustrates an example of a structure of a cell string in the memory block of FIG. 12 according to example embodiments.

FIG. 14A is a schematic diagram of a connection of the memory cell array to the page buffer circuit in FIG. 9, according to example embodiments.

FIG. 14B illustrates a page buffer in detail according to example embodiments.

FIG. 15 is a block diagram illustrating the control circuit in the nonvolatile memory device of FIG. 9 according to example embodiments.

FIG. 16 is a block diagram illustrating the voltage generator in the nonvolatile memory device of FIG. 9 according to example embodiments.

FIG. 17 is a block diagram illustrating an example of the address decoder in the nonvolatile memory device of FIG. 9 according to example embodiments.

FIG. 18 is a diagram a plurality of program loops for an incremental step pulse programming according to example embodiments.

FIG. 19 is a diagram illustrating operation periods included in each of the program loops in FIG. 18 according to example embodiments.

FIG. 20 is a graph showing a threshold voltage distributions of memory cells according to example embodiments.

FIG. 21 is a block diagram illustrating an example of a digital temperature sensor in the nonvolatile memory device of FIG. 9 according to example embodiments.

FIG. 22A illustrates a digital temperature code based on the operating temperature according to example embodiments.

FIG. 22B illustrates a digital temperature code based on the operating temperature according to example embodiments.

FIGS. 23A and 23B illustrate a channel and lines in a memory block according to example embodiments, respectively.

FIGS. 24A, 24B, 24C and 24D illustrate examples of adjusting the second number in the second zone of unselected word-lines based on the operating temperature according to example embodiments, respectively.

FIGS. 25A, 25B, 25C and 25D illustrate examples of adjusting the second number in the second zone of unselected word-lines based on the operating temperature according to example embodiments, respectively.

FIG. 26A is a flow chart illustrating a method of operating a nonvolatile memory device according to example embodiments.

FIG. 26B is a flow chart illustrating an operation of setting the second zone in the method of FIG. 26A according to example embodiments.

FIG. 27 is a block diagram illustrating a storage device according to example embodiments.

### DETAILED DESCRIPTION

Various example embodiments will be described more fully hereinafter with reference to the accompanying drawings, in which some example embodiments are shown. Each example embodiment provided in the following description is not excluded from being associated with one or more features of another example or another example embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation.

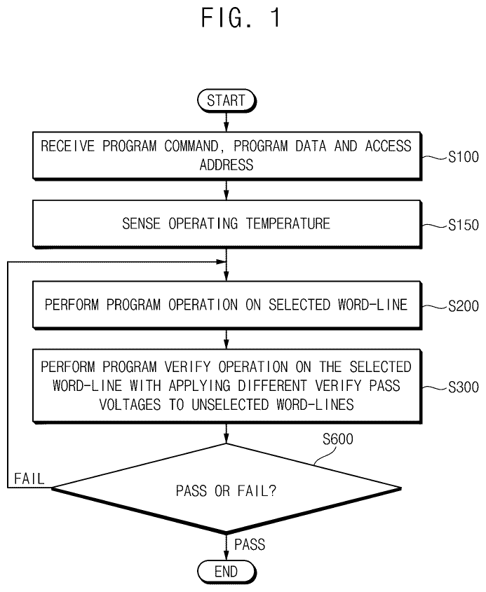

FIG. 1 is a flow chart illustrating a method of operating a nonvolatile memory device according to example embodiments.

FIG. 1 illustrates a method of operating a nonvolatile memory device including at least one memory block which includes a plurality of cell strings, where each cell string includes a string selection transistor, a plurality of memory cells and a ground selection transistor connected in series in a vertical direction between a bit-line and a common source line. The common source line may be formed in or on a substrate. According to example embodiments, the nonvolatile memory device may include a three-dimensional NAND flash memory device or a vertical NAND flash memory device.

Referring to FIG. 1, the nonvolatile memory device receives a program command, a program data and an access address from an external memory controller (operation S100). The access address may include a block address designating a target memory block among a plurality of memory blocks and a row address designating a selected word-line among a plurality of word-lines of the at least one memory block. A word-line among the plurality of word-lines, designated by the row address may be the selected word-line and word-lines among the plurality of word-lines except the selected word-line may be referred to as unselected word-lines.

A temperature sensor in the nonvolatile memory device senses an operating temperature of the nonvolatile memory device while receiving the program command (operation S150).

A control circuit in the nonvolatile memory controls a program operation to be performed on the selected word-line of the plurality of cell strings during a program execution period of a program loop by applying a program voltage to the selected word-line (operation S200).

The control circuit controls a program verification operation to be performed during a program verification of the program loop by controlling a program verification voltage (e.g., a program verify voltage) to be applied to the selected word-line, and a first verification pass voltage (e.g., a first verify pass voltage) and a second verification pass voltage (e.g., a second verify pass voltage) to be applied to unselected word-lines of the plurality of cell strings (operation S300).

The control circuit determines pass or fail of the program operation of memory cells coupled to the selected word-line based on a result of the program verification operation (operation S600).

When the control circuit determines a program pass (PASS in S600), the method ends. When the control circuit determines a program fail (FAIL in S600), the control circuit increases a voltage level of the program voltage and controls the level-increased program voltage to be applied to the selected word-line (operation S200).

As the operating temperature of the nonvolatile memory device changes, a sensed temperature provided to a sensing node of a page buffer from the memory cells coupled to the selected word-line may change during the program verification operation. The memory cell may be connected to the page buffer through a bit-line.

When a voltage level of a verification pass voltage applied to the unselected word-lines in a hot temperature range is the same as a voltage level of a verification pass voltage applied to the unselected word-lines in a cold temperature range, a sensed current provided to the sensing node of the page buffer may be degraded. However, in a method of operating the nonvolatile memory device according to example embodiments, the verification pass voltage applied to the unselected word-lines may be differently adjusted based on the operating temperature and thus, and thus the sensed current provided to the sensing node may be prevented from being degraded in the cold temperature range. Therefore, reliability of the program verification operation may be enhanced.

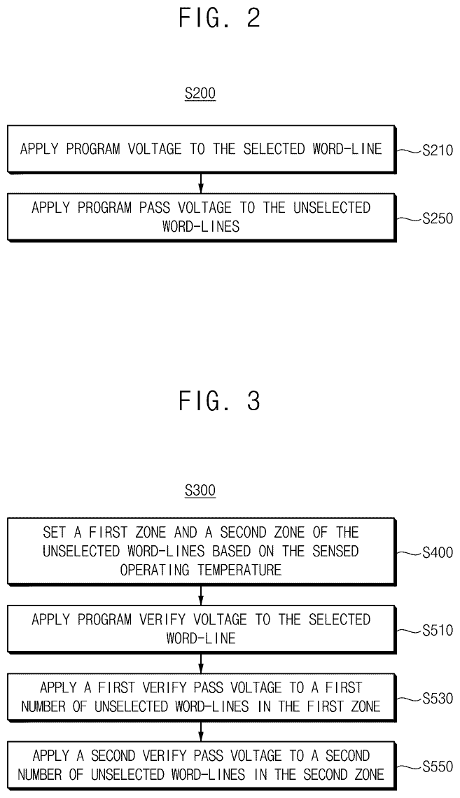

FIG. 2 is a flow chart illustrating an example of performing the program operation on the selected word-line in FIG. 1 according to example embodiments.

Referring to FIG. 2, for performing the program operation on the selected word-line (operation S200), the control circuit controls the program voltage (operation S210) to be applied to the selected word-line and a program pass voltage to be applied to the unselected word-lines (operation S250).

FIG. 3 is a flow chart illustrating an example of performing the program verification operation in FIG. 1 according to example embodiments.

Referring to FIG. 3, for performing the program verification operation (operation S300), the control circuit adjusts (e.g. sets) a number of a first zone of unselected word-lines and a number of a second zone of unselected word-line among the plurality of unselected word-lines based on a sensed operating temperature (operation S400). The number of the first zone of unselected word-lines may be a first number and the number of the second zone of unselected word-lines may be a second number. That is, the first zone may include the first number of unselected word-lines and the second zone may include the second number of unselected word-lines.

The control circuit controls a first verification pass voltage to be applied to the first zone of the unselected word-lines (operation S530) and a second verification pass voltage to be applied to the second zone of unselected word-lines (operation S550). A voltage level of the second verification pass voltage may be lower than a voltage level of the first verification pass voltage.

In example embodiments, the control circuit may identify the second zone based on a position of the selected word-line along the vertical direction. That is, the control circuit may select the second zone as word-lines below the selected word-line in the vertical direction and the first zone may correspond to a zone except the second zone.

In example embodiments, the control circuit may identify the second zone based on a position of the selected word-line along the vertical direction. That is, the control circuit may select the second zone as word-lines above the selected word-line in the vertical direction and the first zone may correspond to a zone except the second zone.

In example embodiments, the control circuit may increase the first number while reducing the second number as the sensed operating temperature decreases. That is, the control circuit may increase the first number and reduce the second number based on a decrease in the sensed operating temperature.

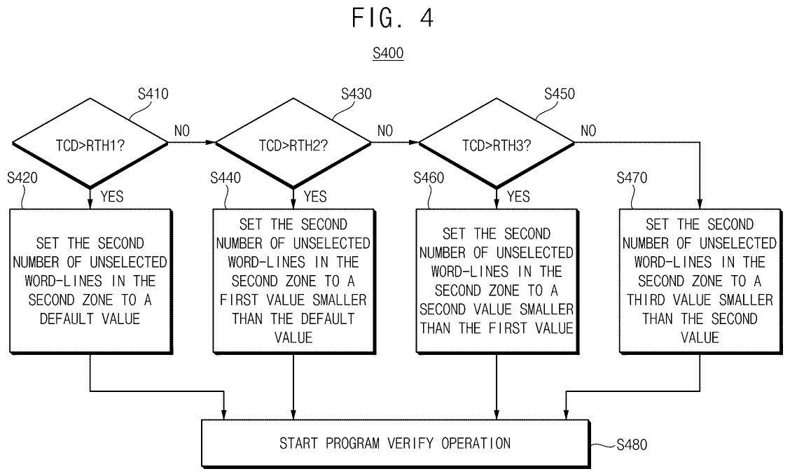

FIG. 4 is a flow chart illustrating an example of adjusting the first number and the second number in in FIG. 3 according to example embodiments.

Referring to FIG. 4, for adjusting the first number and the second number (operation S400), the control circuit determines whether the sensed operating temperature (e.g., a digital temperature code TCD) is greater than a first reference temperature RTH1 (operation S410). That is, the control circuit determines whether the sensed operating temperature is in a first temperature range greater than the first reference temperature RTH1. The first temperature range may correspond to a hot temperature range. When the digital temperature code TCD is greater than the first reference temperature RTH1 (that is, when the sensed operating temperature is in the first temperature range) (YES in S410), the control circuit sets the second number to a default value (operation S420), and starts a program verification operation (operation S480).

When the digital temperature code TCD is not greater than the first reference temperature RTH1 (NO in S410), the control circuit determines whether the sensed operating temperature (e.g., the digital temperature code TCD) is greater than a second reference temperature RTH2 lower than the first reference temperature RTH1 (operation S410). That is, the control circuit determines whether the sensed operating temperature is in a second temperature range between the first reference temperature RTH1 and the second temperature range RTH2. The second temperature range may be a middle temperature range. When the digital temperature code TCD is greater than the second reference temperature RTH2 (that is, when the sensed operating temperature is in the second temperature range) (YES in S430), the control circuit sets the second number to a first value less than the default value (operation S440) and starts the program verification operation (operation S480).

When the digital temperature code TCD is not greater than the second reference temperature RTH2 (NO in S430), the control circuit determines whether the sensed operating temperature (e.g., the digital temperature code TCD) is greater than a third reference temperature RTH3 lower than the second reference temperature RTH2 (operation S450). That is, the control circuit determines whether the sensed operating temperature is in a third temperature range between the second reference temperature RTH2 and the third temperature range RTH3. The third temperature range may be a room temperature range. When the digital temperature code TCD is greater than the third reference temperature RTH3 (that is, when the sensed operating temperature is in the third temperature range) (YES in S450), the control circuit sets the second number to a second value less than the first value (operation S460) and starts the program verification operation (operation S480).

When the digital temperature code TCD is not greater than the third reference temperature RTH3 (NO in S450), the control circuit determines the sensed operating temperature is in a fourth temperature range corresponding to a cold temperature range, sets the second number to a third value less than the second value (operation S470) and starts the program verification operation (operation S480).

Therefore, in the method of operating the nonvolatile memory device according to example embodiments, a number of the unselected word-lines to which the second verification pass voltage, lower than the first verification pass voltage, is applied may be adjusted based on the operating temperature during the program verification operation (that is, a number of the unselected word-lines to which the second verification pass voltage is applied is reduced), and thus the sensed current provided to the sensing node may be prevented from being degraded in the cold temperature range. Therefore, reliability of the program verification operation may be enhanced. That is, the control circuit may adjust the first number and the second number differently based on which of a plurality of temperature ranges corresponds (e.g., includes) the sensed operating temperature during the program verification operation.

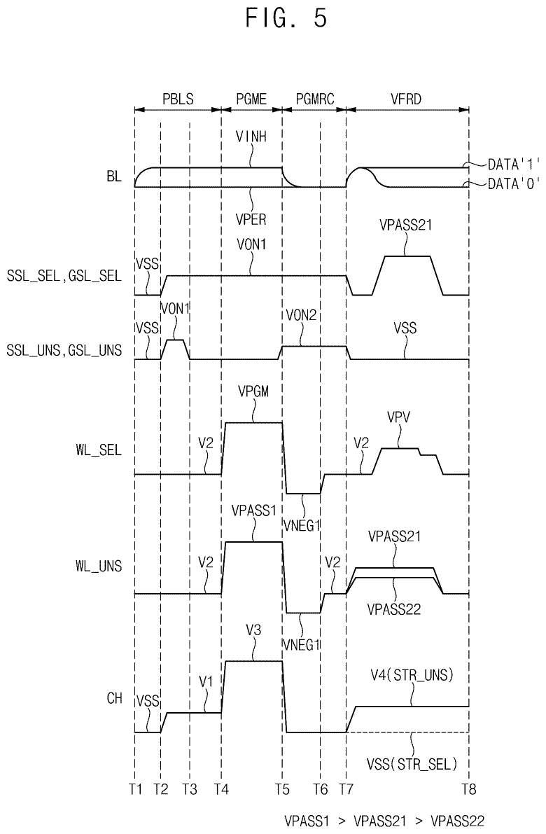

FIG. 5 is a timing diagram illustrating a method of operating a nonvolatile memory device according to example embodiments.

FIG. 5 illustrates an example of a method of programming in a nonvolatile memory device according to example embodiments.

FIG. 5 illustrates a bit-line set-up period PBLS, a program execution period PGME, a program recovery period PGMRC and a verification read period VFRD of one of a plurality of program loops. Time points T1˜T8 represents boundaries of the periods.

Referring to FIG. 5, during the bit-line set-up period PBLS, a ground voltage VSS is applied to a string selection line SSL_SEL and a ground selection line GSL_SEL of a selected cell string from the time point T1 to the time point T2 and a first turn-on voltage VON1 is applied to the string selection line SSL_SEL and the ground selection line GSL_SEL of the selected string from the time point T2 to the time point T4. The ground voltage VSS is applied to a string selection line SSL_UNS and a ground selection line GSL_UNS of an unselected cell string from the time point T1 to the time point T2, the first turn-on voltage VON1 is applied to the string selection line SSL_UNS and the ground selection line GSL_UNS of the unselected cell string from the time point T2 to the time point T3 and the ground voltage VSS is applied to the string selection line SSL_UNS and the ground selection line GSL_UNS of the unselected cell string from the time point T3 to the time point T4. In example embodiments, levels of voltages applied to the string selection line SSL_UNS and the ground selection line GSL_UNS of the unselected cell string may be varied according to a position of the unselected cell string.

A second voltage V2 greater than the ground voltage VSS is applied to a selected word-line WL_SEL and an unselected word-line WL_ULS from the time point T1 to the time point T4. Accordingly, a channel of each of the cell strings is precharged from the ground voltage VSS to the first voltage V1. That is, a channel of each of the cell strings is precharged to the first voltage V1 by performing an unselect string initial precharge (USIP).

The USIP may be performed by using a gate induced drain leakage (GIDL). GIDL indicates a phenomenon that a leakage occurs at a drain of a transistor by a gate of the transistor. For example, when 0V or a negative voltage level is applied to the gate and a sufficiently high positive voltage is applied to the drain, severe band bending may be induced in the oxide near the drain and thus band-to-band tunneling from the valence band of the silicon surface to the conduction band of the silicon body may occur.

The tunneling electrons are attracted to the drain and the drain current increases. The semiconductor substrate is biased by a ground voltage, and holes are attracted to the semiconductor substrate of a relatively low voltage. The gate voltage of a negative voltage level is used to turn off the transistor, but the transistor operates as if it is turned on because the drain current of the GIDL current increases due to the GIDL phenomenon. The GIDL current increases as the gate voltage is decreased and/or the drain voltage is increased.

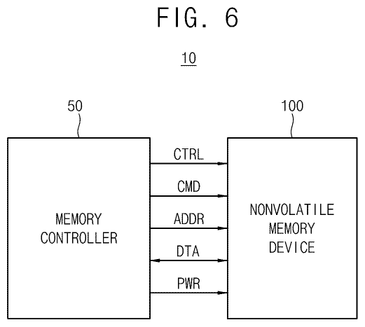

The channels of each of the cell strings may be precharged by using the GIDL. For generating the GIDL phenomenon, a string selection transistor of a cell string, a ground selection transistor of a cell string, or a GIDL transistor may be used, which will be described with reference to FIGS. 6A through 6D.

A program inhibit voltage VINH or a program permission voltage VPER is applied to a bit-line BL based on a value of write data at a starting point T1 of the bit-line set-up period PBLS.

During the program execution period PGME between the time point T4 and the time point T5, successive to the bit-line set-up period PBLS, the first turn-on voltage VON1 is applied to string selection line SSL_SEL and the ground selection line GSL_SEL of the selected string, a program voltage VPGM is applied to the selected word-line WL_SEL and a program pass voltage VPASS1 is applied to the unselected word-line WL_UNS. Accordingly, voltage level of the channel CH of each of the cell strings is increased to a third voltage V3. During the program execution period PGME, the level of the bit-line BL is maintained at the program inhibit voltage VINH or the program permission voltage VPER based on the value of the write data.

During the program recovery period PGMRC between the time point T5 and the time point T7, successive to the program execution period PGME, the first turn-on voltage VON1 is applied to the string selection line SSL_SEL and the ground selection line GSL_SEL of the selected string, a second turn-on voltage VON2 lower than the first turn-on voltage VON1 is applied to the string selection line SSL_UNS and the ground selection line GSL_UNS of the unselected cell string. Accordingly, voltage level of the channel CH of each of the cell strings is increased to a third voltage V3. In addition, after a first negative voltage VNEG1 is applied to the selected word-line WL_SEL and the unselected word-line WL_UNS from the time point T5 and to the time point T6, the second voltage V2 is applied to the selected word-line WL_SEL and the unselected word-line WL_UNS from the time point T6 and to the time point T7. The selected word-line WL_SEL and the unselected word-line WL_UNS are recovered to the second voltage V2 after selected word-line WL_SEL and the unselected word-line WL_UNS are recovered to the first negative voltage VNEG1. Because the first turn-on voltage VON1 is applied to the string selection line SSL_SEL and the ground selection line GSL_SEL of the selected string, and the second turn-on voltage VON2 is applied to string selection line SSL_UNS and the ground selection line GSL_UNS of the unselected cell string, the selected cell string and the unselected cell string are open, and thus the voltage level of the channel CH of each of the cell strings is lowered to a voltage level around the ground voltage VSS, and is maintained. The voltage level of the bit-line BL converges to the program permission voltage VPER during the program recovery period PGMRC.

During the verification read period VFRD between the time point T7 and the time point T8, successive to the recovery period PGMRC, a first verification pass voltage VPASS21 is applied to string selection line SSL_SEL and the ground selection line GSL_SEL of the selected string, and the ground voltage VSS is applied to the string selection line SSL_UNS and the ground selection line GSL_UNS of the unselected cell string. In addition, a verification read voltage VPV is applied to the selected word-line WL_SEL, the first verification pass voltage VPASS21 is applied to a portion of the unselected word-line WL_UNS and a second verification pass voltage VPASS22 is applied to another portion of the unselected word-line WL_UNS. Therefore, a voltage level of the channel of the selected cell string STR_SEL is maintained at a voltage level around the ground voltage VSS, and a voltage level of the channel of the unselected cell string STR_UNS is increased to a fourth voltage V4. The fourth voltage V4 may be lower than the third voltage V3 and may be greater than the first voltage V1. Therefore, the soft erase which may occur in the unselected cell string STR_UNS and the hot carrier injection which may occur at an edge of the selected cell string STR_SEL may be prevented.

A voltage level of the program pass voltage VPASS1 is greater than a voltage level of the first verification pass voltage VPASS21, and a voltage level of the second verification pass voltage VPASS22 is lower than the first verification pass voltage VPASS21.

Assuming that a voltage level (i.e., a potential) of the channel, which is not lowered during the program recovery period PGMRC, has a first level corresponding to a precharged voltage. During the verification read period VFRD, when the verification read voltage VPV is applied to the selected word-line WL_SEL and a verification pass voltage is applied to the unselected word-line WL_UNS, a voltage level of the unselected cell string has a high level corresponding to the first level and the levels of the verification pass voltage. Accordingly, the soft erase may occur in memory cells of the unselected cell string due to high voltage level of the channel of the unselected cell string. In addition, because a voltage level of the channel of the selected cell string rapidly changes from the first level to the level of the ground voltage VSS, leakage current is HCI-injected to a string selection transistor or a ground selection transistor of the selected cell string due to rapid change of the channel and a threshold voltage of the string selection transistor or the ground selection transistor may increase.

Additionally, during a bit-line precharge period before the verification read period VFRD, all of the bit-lines may be initialized by the same bit-line precharge voltage. A voltage of a bit-line is developed to a voltage corresponding to ‘1’ or ‘0 ’ depending on the threshold voltage state of the selected memory cell during the verification read period VFRD. The data stored in the selected memory cell may be determined by sensing the voltage development of the bit-line.

A number of unselected word-lines to which the second verification pass voltage VPASS22 may be adjusted based on an operating temperature of the nonvolatile memory device. The number of the unselected word-lines to which the second verification pass voltage VPASS22 is applied is reduced as the operating temperature decreases, and the sensed current provided to a sensing node of a page buffer may be prevented from being degraded in the cold temperature range.

FIG. 6 is a block diagram illustrating a memory system according to example embodiments.

Referring to FIG. 6, a memory system (e.g., a storage device) 10 may include a memory controller 50 and a nonvolatile memory device 100.

In example embodiments, each of the memory controller 50 and the nonvolatile memory device 100 may be provided with the form of a chip, a package, or a module. Alternatively, the memory controller 50 and the nonvolatile memory device 100 may be packaged into one of various packages.

The nonvolatile memory device 100 may perform an erase operation, a program operation or a read operation under control of the memory controller 50. The nonvolatile memory device 100 receives a command CMD, an address ADDR and data DTA through input/output lines from the memory controller 50 for performing such operations. In addition, the nonvolatile memory device 100 may receive a control signal CTRL through a control line from the memory controller 50. In addition, the nonvolatile memory device 100 may receive a power PWR through a power line from the memory controller 50.

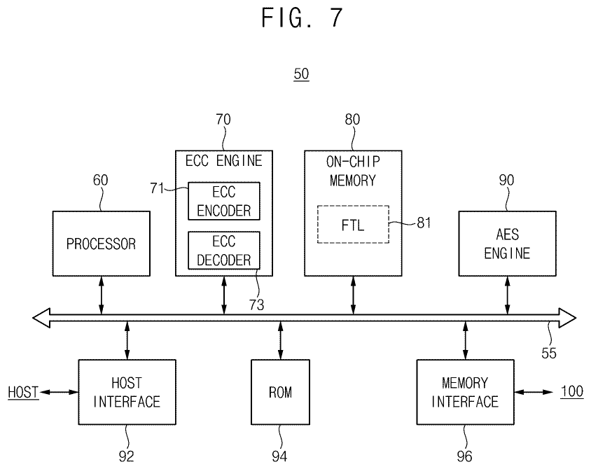

FIG. 7 is a block diagram illustrating an example of the memory controller in the memory system in FIG. 6 according to example embodiments.

Referring to FIG. 7, the memory controller 50 may include a processor 60, an error correction code (ECC) engine 70, an on-chip memory 80, an advanced encryption standard (AES) engine 90, a host interface 92, a read-only memory (ROM) 94 and a memory interface 96 which are connected via a bus 55.

The processor 60 may control an overall operation of the memory controller 50. The processor 60 may control the ECC engine 70, the on-chip memory 80, the AES engine 90, the host interface 92, the ROM 94 and the memory interface 96. The processor 60 may include one or more cores (e.g., a homogeneous multi-core or a heterogeneous multi-core). The processor 60 may be or include, for example, at least one of a central processing unit (CPU), an image signal processing unit (ISP), a digital signal processing unit (DSP), a graphics processing unit (GPU), a vision processing unit (VPU), and a neural processing unit (NPU). The processor 60 may execute various application programs (e.g., a flash translation layer (FTL) 81 and firmware) loaded onto the on-chip memory 80.

The on-chip memory 80 may store various application programs that are executable by the processor 60. The on-chip memory 80 may operate as a cache memory adjacent to the processor 60. The on-chip memory 80 may store a command, an address, and data to be processed by the processor 60 or may store a processing result of the processor 60. The on-chip memory 80 may be, for example, a storage medium or a working memory including a latch, a register, a static random access memory(SRAM), a dynamic random access memory (DRAM), a thyristor random access memory (TRAM), a tightly coupled memory (TCM), etc.

The processor 60 may execute the FTL 81 loaded onto the on-chip memory 80. The FTL 81 may be loaded onto the on-chip memory 80 as firmware or a program stored in the nonvolatile memory device 100. The FTL 81 may manage mapping between a logical address provided from a host and a physical address of the nonvolatile memory device 100 and may include an address mapping table manager managing and updating an address mapping table. The FTL 81 may further perform a garbage collection operation, a wear leveling operation, and the like, as well as the address mapping described above. The FTL 81 may be executed by the processor 60 for addressing one or more of the following aspects of the nonvolatile memory device 100: overwrite-or in-place write-impossible, a life time of a memory cell, a limited number of program-erase (PE) cycles, and an erase speed slower than a write speed. The FTL 81 may provide the nonvolatile memory device 100 mapping information between the logical address and the physical address.

Memory cells of the nonvolatile memory device 100 may have the physical characteristic that a threshold voltage distribution varies due to causes, such as a program elapsed time, a temperature, program disturbance, read disturbance and etc. For example, data stored at the nonvolatile memory device 100 becomes erroneous due to the above causes.

The memory controller 50 may utilize a variety of error correction techniques to correct such errors. For example, the memory controller 50 may include the ECC engine 70. The ECC engine 70 may correct errors which occur in the data stored in the nonvolatile memory device 100. The ECC engine 70 may include an ECC encoder 71 and an ECC decoder 73. The ECC encoder 71 may perform an ECC encoding operation on data to be stored in the nonvolatile memory device 100. The ECC decoder 73 may perform an ECC decoding operation on data read from the nonvolatile memory device 100.

The ROM 94 may store a variety of information, needed for the memory controller 50 to operate, in firmware.

The AES engine 90 may perform at least one of an encryption operation and a decryption operation on data input to the memory controller 50 by using a symmetric-key algorithm. The AES engine 90 may include an encryption module and a decryption module. For example, the encryption module and the decryption module may be implemented as separate modules. For another example, one module capable of performing both encryption and decryption operations may be implemented in the AES engine 90.

The memory controller 50 may communicate with the host through the host interface 92. For example, the host interface 92 may include Universal Serial Bus (USB), Multimedia Card (MMC), embedded-MMC, peripheral component interconnection (PCI), PCI-express, Advanced Technology Attachment (ATA), Serial-ATA, Parallel-ATA, small computer small interface (SCSI), enhanced small disk interface (ESDI), Integrated Drive Electronics (IDE), Mobile Industry Processor Interface (MIPI), Nonvolatile memory express (NVMe), Universal Flash Storage (UFS), and etc. The memory controller 50 may communicate with the nonvolatile memory device 100 through the memory interface 96.

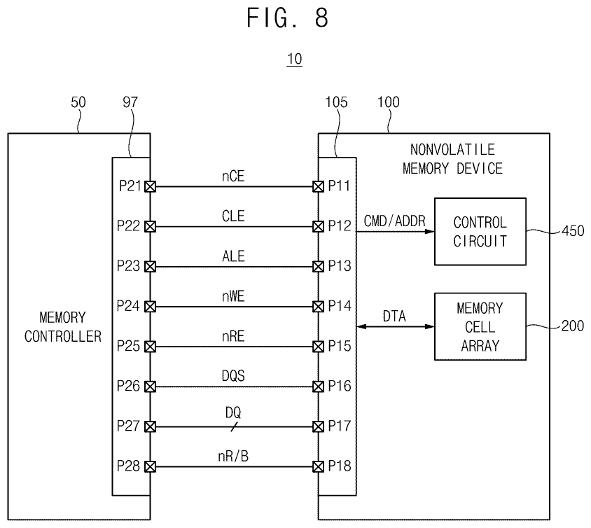

FIG. 8 illustrates a connection example of the memory controller and the nonvolatile memory device in FIG. 6 according to example embodiments.

Referring to FIG. 8, the memory system 10 may include the nonvolatile memory device 100 and the memory controller 50. FIG. 8 illustrates an interface between the nonvolatile memory device 100 and the memory controller 50 in detail.

The nonvolatile memory device 100 may include first to eighth pins P11, P12, P13, P14, P15, P16, P17 and P18, an interface circuit 105, a control circuit 450 and a memory cell array 200. The interface circuit 105 may be referred to as a first interface circuit or a memory interface circuit.

The interface circuit 105 may receive a chip enable signal nCE from the memory controller 50 through the first pin P11. The interface circuit 105 may transmit and receive signals to and from the memory controller 50 through the second to eighth pins P12 to P18 in response to the chip enable signal nCE. For example, when the chip enable signal nCE is in an enable state (e.g., a low level), the interface circuit 105 may transmit and receive signals to and from the memory controller 50 through the second to eighth pins P12 to P18.

The interface circuit 105 may receive a command latch enable signal CLE, an address latch enable signal ALE and a write enable signal nWE from the memory controller 50 through the second to fourth pins P12 to P14. The interface circuit 105 may receive a data signal DQ from the memory controller 50 through the seventh pin P17 or may transmit the data signal DQ to the memory controller 50. A command CMD, an address ADDR and data DTA may be transmitted via the data signal DQ. For example, the data signal DQ may be transmitted through a plurality of data signal lines. In this case, the seventh pin P17 may include a plurality of pins respectively corresponding to a plurality of data signals DQ(s).

The interface circuit 105 may obtain the command CMD from the data signal DQ, which is received in an enable section (e.g., a high-level state) of the command latch enable signal CLE based on toggle time points of the write enable signal nWE. The interface circuit 105 may obtain the address ADDR from the data signal DQ, which is received in an enable section (e.g., a high-level state) of the address latch enable signal ALE based on the toggle time points of the write enable signal nWE.

In some example embodiments, the write enable signal nWE may be maintained at a static state (e.g., a high level or a low level) and may toggle between the high level and the low level. For example, the write enable signal nWE may toggle in a section in which the command CMD or the address ADDR is transmitted. Thus, the interface circuit 105 may obtain the command CMD or the address ADDR based on the toggle time points of the write enable signal nWE.

The interface circuit 105 may receive a read enable signal nRE from the memory controller 50 through the fifth pin P15. The interface circuit 105 may receive a data strobe signal DQS from the memory controller 50 through the sixth pin P16 or may transmit the data strobe signal DQS to the memory controller 50.

In a data output operation of the nonvolatile memory device 100, the interface circuit 105 may receive the read enable signal nRE, which toggles through the fifth pin P15, before outputting the data DTA. The interface circuit 105 may generate the data strobe signal DQS, which toggles based on the toggling of the read enable signal nRE. For example, the interface circuit 105 may generate the data strobe signal DQS, which starts toggling after a predetermined delay (e.g., tDQSRE), based on a toggling start time of the read enable signal nRE. The interface circuit 105 may transmit the data signal DQ including the data DTA based on a toggle time point of the data strobe signal DQS. Thus, the data DTA may be aligned with the toggle time point of the data strobe signal DQS and may be transmitted to the memory controller 50.

In a data input operation of the nonvolatile memory device 100, when the data signal DQ including the data DTA is received from the memory controller 50, the interface circuit 105 may receive the data strobe signal DQS, which toggles, along with the data DTA from the memory controller 50. The interface circuit 105 may obtain the data DTA from the data signal DQ based on toggle time points of the data strobe signal DQS. For example, the interface circuit 105 may sample the data signal DQ at rising and falling edges of the data strobe signal DQS and may obtain the data DTA.

The interface circuit 105 may transmit a ready/busy signal nR/B to the memory controller 50 through the eighth pin P18. The interface circuit 105 may transmit state information of the nonvolatile memory device 100 through the ready/busy signal nR/B to the memory controller 50. When the nonvolatile memory device 100 is in a busy state (e.g., when operations are being performed in the nonvolatile memory device 100), the interface circuit 105 may transmit the ready/busy signal nR/B indicating the busy state to the memory controller 50. When the nonvolatile memory device 100 is in a ready state (e.g., when operations are not performed or are completed in the nonvolatile memory device 100), the interface circuit 105 may transmit the ready/busy signal nR/B indicating the ready state to the memory controller 50.

The control circuit 450 may control overall operations of the nonvolatile memory device 100. The control circuit 450 may receive the command CMD and the address ADDR obtained from the interface circuit 105. The control circuit 450 may generate control signals for controlling other components of the nonvolatile memory device 100 in response to the received command CMD and the received address ADDR. For example, the control circuit 450 may generate various control signals for programming the data DTA to the memory cell array 200 or for reading the data DTA from the memory cell array 200.

The memory cell array 200 may store the data DTA obtained from the interface circuit 105, under the control of the control circuit 450. The memory cell array 200 may output the stored data DTA to the interface circuit 105 under the control of the control circuit 450.

The memory cell array 200 may include a plurality of nonvolatile memory cells.

The memory controller 50 may include first to eighth pins P21, P22, P23, P24, P25, P26, P27 and P28 and an interface circuit 97. The interface circuit 97 may be referred to as a second interface circuit or a controller interface circuit. The interface circuit 97 may correspond to the memory interface 96 in FIG. 7. The first to eighth pins P21 to P28 may correspond to the first to eighth pins P11 to P18 of the nonvolatile memory device 100, respectively.

The interface circuit 97 may transmit the chip enable signal nCE to the nonvolatile memory device 100 through the first pin P21. The interface circuit 97 may transmit and receive signals to and from the nonvolatile memory device 100, which is selected by the chip enable signal nCE, through the second to eighth pins P22 to P28.

The interface circuit 97 may transmit the command latch enable signal CLE, the address latch enable signal ALE and the write enable signal nWE to the nonvolatile memory device 100 through the second to fourth pins P22 to P24. The interface circuit 97 may transmit or receive the data signal DQ to and from the nonvolatile memory device 100 through the seventh pin P27.

The interface circuit 97 may transmit the data signal DQ including the command CMD or the address ADDR to the nonvolatile memory device 100 along with the write enable signal nWE, which toggles. The interface circuit 97 may transmit the data signal DQ including the command CMD to the nonvolatile memory device 100 by transmitting the command latch enable signal CLE having an enable state. Also, the interface circuit 87 may transmit the data signal DQ including the address ADDR to the nonvolatile memory device 100 by transmitting the address latch enable signal ALE having an enable state.

The interface circuit 97 may transmit the read enable signal nRE to the nonvolatile memory device 100 through the fifth pin P25. The interface circuit 97 may receive or transmit the data strobe signal DQS from or to the nonvolatile memory device 100 through the sixth pin P26.

The interface circuit 97 may receive the ready/busy signal nR/B from the nonvolatile memory device 100 through the eighth pin P28. The interface circuit 97 may determine state information of the nonvolatile memory device 100 based on the ready/busy signal nR/B.

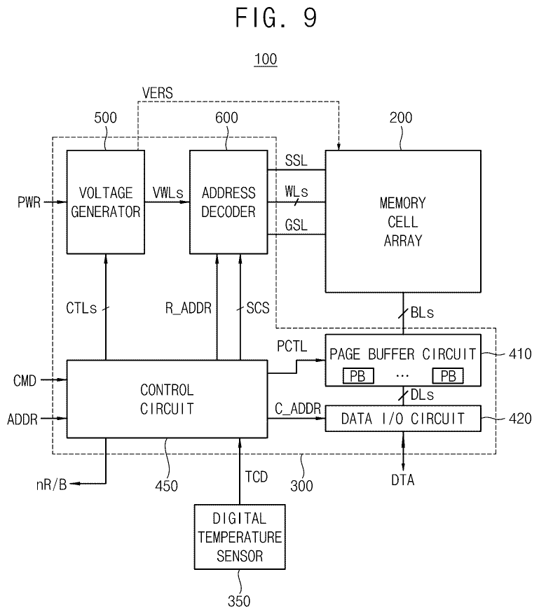

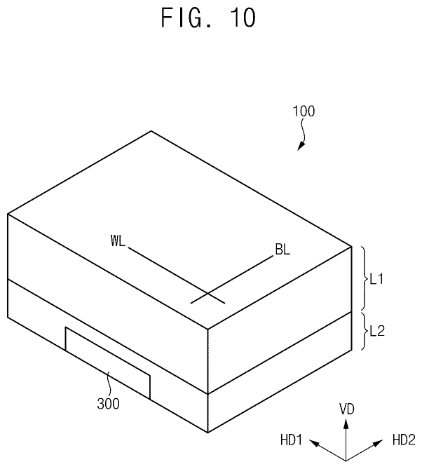

FIG. 9 is a block diagram illustrating an example of the nonvolatile memory device in the memory system of FIG. 6 according to example embodiments.

Referring to FIG. 9, the nonvolatile memory device 100 may include a memory cell array 200 and a peripheral circuit 300. The peripheral circuit 300 may include an address decoder 600, a page buffer circuit 410, a data input/output (I/O) circuit 420, a control circuit 450 and a voltage generator 500. In example embodiments, the nonvolatile memory device 100 may further include a digital temperature sensor 350. The digital temperature sensor 350 may be included in the peripheral circuit 300. The digital temperature sensor 350 may be disposed at an outside of the peripheral circuit 300. The digital temperature sensor 350 may be referred to as a temperature sensor.

The memory cell array 200 may be coupled to the address decoder 600 through a string selection line SSL, a plurality of word-lines WLs, and a ground selection line GSL. In addition, the memory cell array 200 may be coupled to the page buffer circuit 410 through a plurality of bit-lines BLs. The memory cell array 200 may include a plurality of nonvolatile memory cells coupled to the plurality of word-lines WLs and the plurality of bit-lines BLs.

In some example embodiments, the memory cell array 200 may be a three-dimensional memory cell array, which is formed on a substrate in a three-dimensional structure (or a vertical structure). In this case, the memory cell array 200 may include vertical cell strings (e.g., cell strings) that are vertically oriented such that at least one memory cell is located over another memory cell.

The control circuit 450 may receive the command (signal) CMD and the address (signal) ADDR from the memory controller 50 and control an erase loop, a program loop and a read operation of the nonvolatile memory device 100 based on the command CMD and the address ADDR. The program loop may include a program operation and a program verification operation. The erase loop may include an erase operation and an erase verification operation.

For example, the control circuit 450 may generate control signals CTLs to control the voltage generator 500, may generate a control signal PCTL to control the page buffer circuit 410 and may generate a switching control signal SCS to control the address decoder 600 based on the command CMD, the digital temperature code TCD and word-line group information GRI. The control circuit 450 may provide the control signals CTLs to the voltage generator 500, may provide the control signal PCTL to the page buffer circuit 410 and may provide the switching control signal SCS to the address decoder 600.

In addition, the control circuit 450 may generate a row address R_ADDR and a column address C_ADDR based on the address ADDR. The control circuit 450 may provide the row address R_ADDR to the address decoder 600 and provide the column address C_ADDR to the data I/O circuit 420. In addition, the control circuit 450 may generate the ready/busy signal nR/B indicating operating status of the nonvolatile memory device 100.

The address decoder 600 may be coupled to the memory cell array 200 through the string selection line SSL, the plurality of word-lines WLs, and the ground selection line GSL. During the program operation or the read operation, the address decoder 600 may determine one of the plurality of word-lines WLs as a selected word-line and determine rest of the plurality of word-lines WLs except for the selected word-line as unselected word-lines based on the row address R_ADDR.

The voltage generator 500 may generate word-line voltages VWLs, which are required for the operation of the nonvolatile memory device 100, based on the control signals CTLs. The voltage generator 500 may receive the power PWR from the memory controller 50. The word-line voltages VWLs may be applied to the plurality of word-lines WLs through the address decoder 600.

For example, during the erase operation, the voltage generator 500 may apply an erase voltage VERS to a channel of the cell strings of the target memory block, may apply an word-line erase voltage to word-lines of the target memory block and may apply an erase inhibit voltage to the word-lines of the target memory block. During the erase verification operation, the voltage generator 500 may apply an erase verification voltage to the word-lines of the target memory block or sequentially apply the erase verification voltage to the word-lines on a word-line basis. In example embodiments, the voltage generator 500 may apply the erase voltage VERS the memory cell array 200.

For example, during the program operation, the voltage generator 500 may apply a program voltage to the selected word-line and may apply a program pass voltage to the unselected word-lines. In addition, during the program verification operation, the voltage generator 500 may apply a program verification voltage to the selected word-line and may apply a first verification pass voltage and a second verification pass voltage to the unselected word-lines. In addition, during the read operation, the voltage generator 500 may apply a read voltage to the selected word-line and may apply a read pass voltage to the unselected word-lines.

The page buffer circuit 410 may be coupled to the memory cell array 200 through the plurality of bit-lines BLs. The page buffer circuit 410 may include a plurality of page buffers PBs. The page buffer circuit 410 may temporarily store data to be programmed in a selected page or data read out from the selected page.

The data I/O circuit 420 may be coupled to the page buffer circuit 410 through a plurality of data lines DLs. During the program operation, the data I/O circuit 420 may receive program data DTA from the memory controller 50 and provide the program data DTA to the page buffer circuit 410 based on the column address C_ADDR received from the control circuit 450. During the read operation, the data I/O circuit 420 may provide read data DTA, which are stored in the page buffer circuit 410, to the memory controller 50 based on the column address C_ADDR received from the control circuit 450.

The digital temperature sensor 350 may sense operating temperature of the nonvolatile memory device 100 and may provide the control circuit 450 with a digital temperature code TCD corresponding to the sensed operating temperature based on the sensed operating temperature. Values of the digital temperature code TCD may be proportional or inversely proportional to the sensed operating temperature.

The control circuit 450 may control operations in FIGS. 1 through 4 to be performed by controlling the voltage generator 500 and the address decoder 600.

The control circuit 450 may set a first zone of unselected word-lines and a second zone of unselected word-lines among the plurality of unselected word-lines and may adjust a second number in the second zone of unselected word-lines according to the sensed operating temperature based on the digital temperature code TCD.

FIG. 10 schematically illustrates a structure of the nonvolatile memory device of FIG. 9 according to example embodiments.

Referring to FIG. 10, the nonvolatile memory device 100 may include a first semiconductor layer L1 and a second semiconductor layer L2, and the first semiconductor layer L1 may be stacked in a vertical direction VD with respect to the second semiconductor layer L2. The second semiconductor layer L2 may be under the first semiconductor layer L1 in the vertical direction VD, and accordingly, the second semiconductor layer L2 may be close to a substrate.

In example embodiments, the memory cell array 200 in FIG. 9 may be formed (or, provided) on the first semiconductor layer L1, and the peripheral circuit 300 in FIG. 9 may be formed (or, provided) on the second semiconductor layer L2. Accordingly, the nonvolatile memory device 100 may have a structure in which the memory cell array 200 is provided on the peripheral circuit 300, that is, a cell over periphery (COP) structure. The COP structure may effectively reduce an area in a horizontal direction and improve the degree of integration of the nonvolatile memory device 100.

In example embodiments, the second semiconductor layer L2 may include the substrate, and transistors and metal patterns for wiring transistors may be formed on the substrate. Thus, the peripheral circuit 300 may be formed in the second semiconductor layer L2. After the peripheral circuit 300 is formed on the second semiconductor layer L2, the first semiconductor layer L1 including the memory cell array 200 may be formed, and the metal patterns for connecting the word-lines WL and the bit-lines BL of the memory cell array 200 to the peripheral circuit 200 formed in the second semiconductor layer L2 may be formed. For example, the word-lines WL may extend in a first horizontal direction HD1 and the bit-lines BL may extend in a second horizontal direction HD2.

As the number of stages of memory cells in the memory cell array 200 increases with the development of semiconductor processes, that is, as the number of stacked word-lines WL increases, an area of the memory cell array 200 may decrease, and accordingly, an area of the peripheral circuit 300 may also be reduced. According to an example embodiment, to reduce an area of a region occupied by the page buffer circuit 410, the page buffer circuit 410 may have a structure in which the page buffer unit and the cache latch are separated from each other, and may connect sensing nodes included in each of the page buffer units commonly to a combined sensing node.

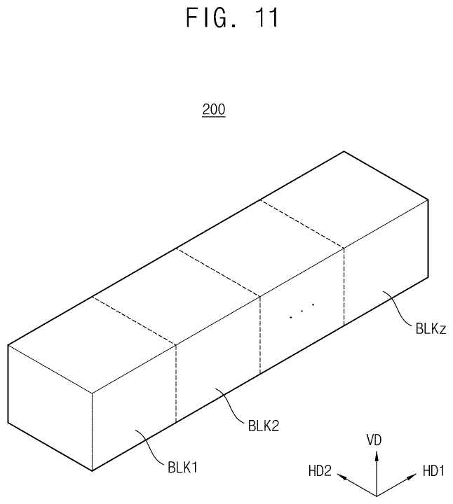

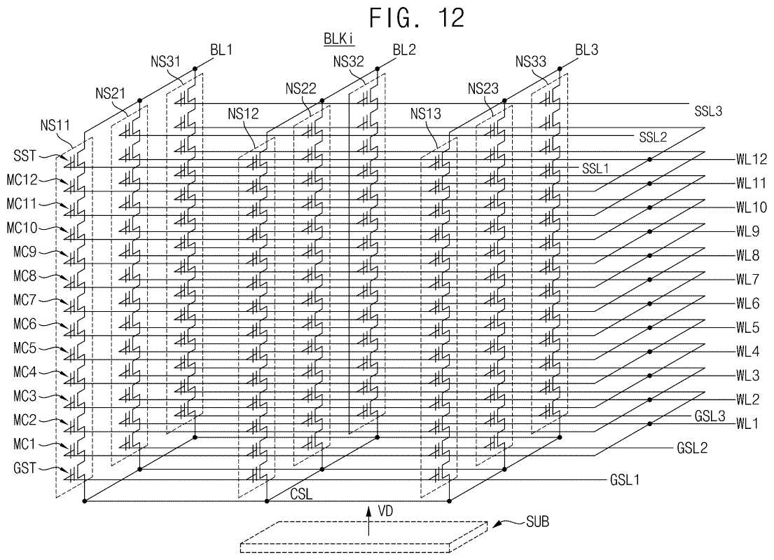

FIG. 11 is a block diagram illustrating an example of the memory cell array in the nonvolatile memory device of FIG. 9 according to example embodiments.

Referring to FIG. 11, the memory cell array 200 may include a plurality of memory blocks BLK1, BLK2 to BLKz. Here, z is a natural number greater than two. The memory blocks BLK1, BLK2 to BLKz extend along the first horizontal direction HD1, the second horizontal direction HD2, and the vertical direction VD. In some example embodiments, the memory blocks BLK1, BLK2 to BLKz are selected by the address decoder 600 in FIG. 9. For example, the address decoder 600 may select a memory block BLK corresponding to a block address among the memory blocks BLK1, BLK2 to BLKz.

The first horizontal direction HD1 and the second horizontal direction HD2 cross each other and are substantially parallel to an upper surface to a substrate and the vertical direction VD is substantially perpendicular to the upper surface of the substrate.

FIG. 12 is a circuit diagram illustrating one of the memory blocks of FIG. 11 according to example embodiments.

A memory block BLKi of FIG. 12 may be formed on a substrate SUB in a three-dimensional structure (or a vertical structure). Here, i may be one of 1 to z. For example, a plurality of cell strings included in the memory block BLKi may be formed in the vertical direction VD perpendicular to the substrate SUB.

Referring to FIG. 12, the memory block BLKi may include a plurality of (memory) cell strings NS11, NS21, NS31, NS12, NS22, NS32, NS13, NS23 and NS33 (hereinafter, denoted as NS11 to NS33) coupled between bit-lines BL1, BL2 and BL3 and a common source line CSL. Each of the cell strings NS11 to NS33 may include a string selection transistor SST, a plurality of memory cells MC1, MC2, MC3, MC4, MC5, MC6, MC7, MC8, MC9, MC10, MC11 and MC12 (hereinafter, denoted as MC1 to MC12), and a ground selection transistor GST. In FIG. 12, each of the cell strings NS11 to NS33 is illustrated to include twelve memory cells MC1 to MC12. However, example embodiments are not limited thereto. In some example embodiments, each of the cell strings NS11 to NS33 may include any number of memory cells.

The string selection transistor SST may be connected to corresponding string selection lines SSL1, SSL2 and SSL3. The plurality of memory cells MC1 to MC12 may be connected to corresponding word-lines WL1, WL2, WL3, WL4, WL5, WL6, WL7, WL8, WL9, WL10, WL11 and WL12 (hereinafter, denoted as WL1 to WL12), respectively. The ground selection transistor GST may be connected to corresponding ground selection lines GSL1, GSL2 and GSL3. The string selection transistor SST may be connected to corresponding bit-lines BL1, BL2 and BL3, and the ground selection transistor GST may be connected to the common source line CSL.

Word-lines (e.g., word-line WL1) having the same height may be commonly connected, and the ground selection lines GSL1, GSL2 and GSL3 and the string selection lines SSL1, SSl2 and SSL3 may be separated. In FIG. 12, the memory block BLKi is illustrated to be coupled to twelve word-lines WL1 to WL12 and three bit-lines BL1, BL2 and BL3.

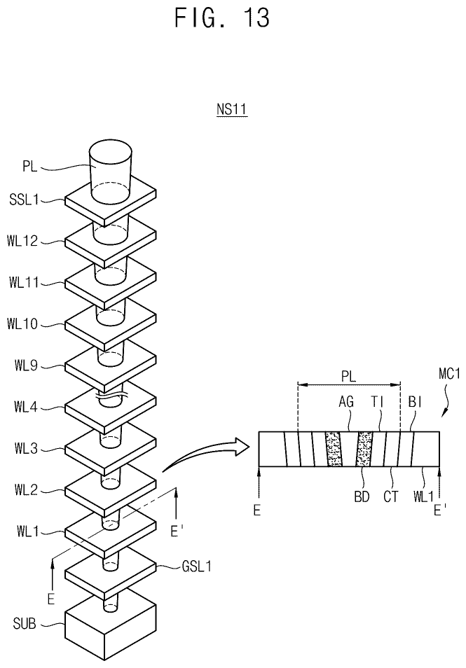

FIG. 13 illustrates an example of a structure of a cell string in the memory block of FIG. 12.

Referring to FIGS. 12 and 13 a pillar PL is provided on the substrate SUB such that the pillar PL extends in a direction perpendicular to the substrate SUB to make contact with the substrate SUB. Each of the ground selection line GSL, the word-lines WL1 to WL12, and the string selection lines SSL illustrated in FIG. 13 may be formed of a conductive material parallel with the substrate SUB, for example, a metallic material. The pillar PL may be in contact with the substrate SUB through the conductive materials forming the string selection lines SSL, the word-lines WL1 to WL12, and the ground selection line GSL.

A sectional view taken along a line E-E′ is also illustrated in FIG. 13. In some example embodiments, a sectional view of a first memory cell MC1 corresponding to a first word-line WL1 is illustrated. The pillar PL may include a cylindrical body BD. An air gap AG may be defined in the interior of the body BD.

The body BD may include P-type silicon and may be an area where a channel will be formed. The pillar PL may further include a cylindrical tunnel insulating layer TI surrounding the body BD and a cylindrical charge trap layer CT surrounding the tunnel insulating layer TI. A blocking insulating layer BI may be provided between the first word-line WL1 and the pillar PL. The body BD, the tunnel insulating layer TI, the charge trap layer CT, the blocking insulating layer BI, and the first word-line WL1 may constitute or be included in a charge trap type transistor that is formed in a direction perpendicular to the substrate SUB or to an upper surface of the substrate SUB. A string selection transistor SST, a ground selection transistor GST, and other memory cells may have the same structure as the first memory cell MC1.

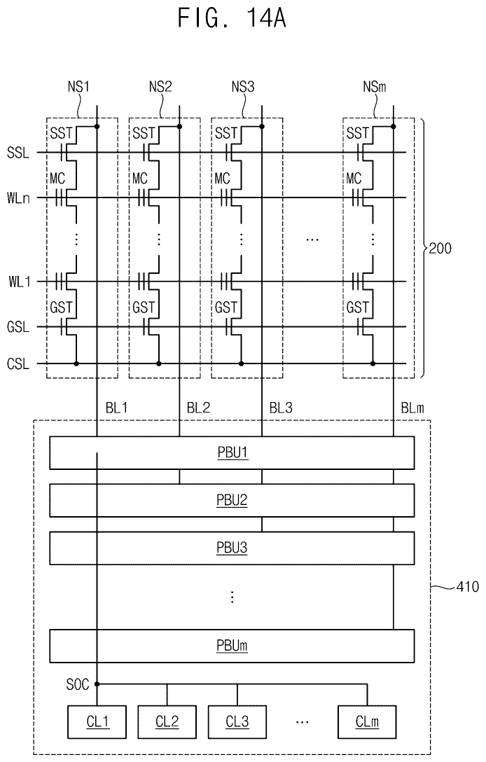

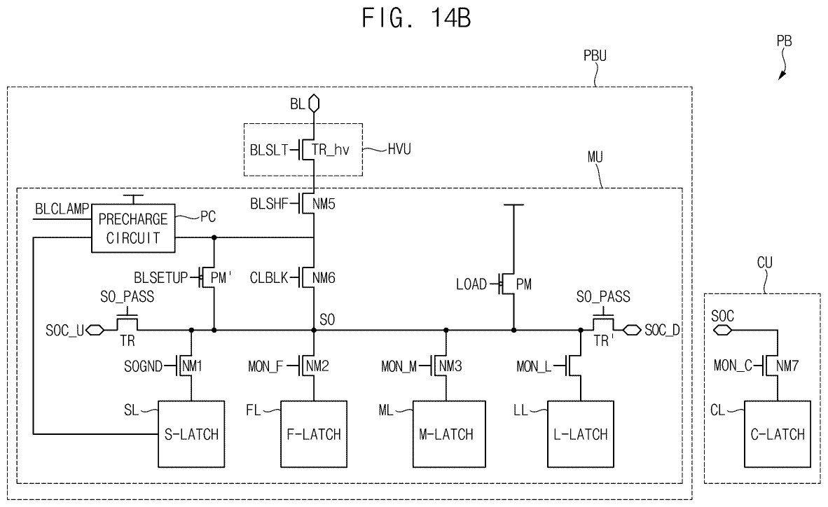

FIG. 14A is a schematic diagram of a connection of the memory cell array to the page buffer circuit in FIG. 9, according to example embodiments.

Referring to FIG. 14A, the memory cell array 200 may include first through m-th cell strings NS1, NS2, NS3, . . . , NSm, each of the first through m-th cell strings NS1, NS2, NS3, . . . , NSm may include a ground select transistor GST connected to the ground select line GSL, a plurality of memory cells MC respectively connected to the first through n-th word-lines WL1, ..., WLn, and a string select transistor SST connected to the string select line SSL, and the ground select transistor GST, the plurality of memory cells MC, and the string select transistor SST may be connected to each other in series. In this case, n may be a positive integer greater than three.

The page buffer circuit 410 may include first through m-th page buffer units PBU1, PBU2, PBU3, . . . , PBUm. The first page buffer unit PB1 may be connected to the first cell string NS1 via the first bit-line BL1, and the m-th page buffer unit PBUm may be connected to the m-th cell string NSm via the m-th bit-line BLm. For example, m may be 8, and the page buffer circuit 410 may have a structure in which page buffer units of eight stages, or, the first through m-th page buffer units PBU1, PBU2, PBU3, . . . , PBUm are arranged in a line. For example, the first through m-th page buffer units PBU1, PBU2, PBU3, . . . , PBUm may be provided in a row along an extension direction of the first through m-th bit-lines BL1, BL2, BL3, . . . , BLm.

The page buffer circuit 410 may further include first through m-th cache latches CL1, CL2, CL3, . . . , CLm respectively corresponding to the first through m-th page buffer units PBU1, PBU2, PBU3, . . . , PBUm. For example, the page buffer circuit 410 may have a structure in which the cache latches of eight stages or the first through m-th cache latches CL1, CL2, CL3, . . . , CLm are arranged in a line. For example, the first through m-th cache latches CL1, CL2, CL3, . . . , CLm may be provided in a row along an extension direction of the first through m-th bit-lines BL1, BL2, BL3, . . . , BLm.

The sensing nodes of each of the first through m-th page buffer units PBU1, PBU2, PBU3, . . . , PBUm may be commonly connected to a combined sensing node SOC. In addition, the first through m-th cache latches CL1, CL2, CL3, . . . , CLm may be commonly connected to the combined sensing node SOC. Accordingly, the first through m-th page buffer units BU1, PBU2, PBU3, . . . , PBUm may be connected to the first through m-th cache latches CL1, CL2, CL3, . . . , CLm via the combined sensing node SOC.

FIG. 14B illustrates a page buffer in detail according to example embodiments.

Referring to FIG. 14B, the page buffer PB may correspond to an example of the page buffer PB in FIG. 9. The page buffer PB may include a page buffer unit PBU and a cache unit CU. Because the cache unit CU includes a cache latch (C-LATCH) CL, and the C-LATCH CL is connected to a data input/output line, the cache unit CU may be adjacent to the data input/output line. Accordingly, the page buffer unit PBU and the cache unit CU may be apart from each other, and the page buffer PB may have a structure in which the page buffer unit PBU and the cache unit CU are apart from each other.

The page buffer unit PBU may include a main unit MU. The main unit MU may include main transistors in the page buffer PB. The page buffer unit PBU may further include a bit-line selection transistor TR_hv that is connected to the bit-line BL and driven by a bit-line selection signal BLSLT. The bit-line select transistor TR_hv may include a high voltage transistor, and accordingly, the bit-line selection transistor TR_hv may be in a different well region from the main unit MU, that is, in a high voltage unit HVU.

The main unit MU may include a sensing latch (S-LATCH) SL, a force latch (F-LATCH) FL, an upper bit latch (M-LATCH) ML and a lower bit latch (L-LATCH) LL. According to an example embodiment, the S-LATCH SL, the F-LATCH FL, the M-LATCH ML, or the L-LATCH LL may be referred to as main latches. The main unit MU may further include a precharge circuit PC capable of controlling a precharge operation on the bit-line BL or a sensing node SO based on a bit-line clamping control signal BLCLAMP, and may further include a transistor PM′ driven by a bit-line setup signal BLSETUP.

The S-LATCH SL may, during a read or program verification operation, store data stored in a memory cell MC or a sensing result of a threshold voltage of the memory cell MC. In addition, the S-LATCH SL may, during a program operation, be used to apply a program bit-line voltage or a program inhibit voltage to the bit-line BL. The F-LATCH FL may be used to improve threshold voltage distribution during the program operation. The F-LATCH FL may store force data. After the force data is initially set to ‘1’, the force data may be converted to ‘0 ’ when the threshold voltage of the memory cell MC enters a forcing region that has a lower voltage than a target region. By utilizing the force data during a program execution operation, the bit-line voltage may be controlled, and the program threshold voltage distribution may be formed narrower.

The M-LATCH ML, the L-LATCH LL, and the C-LATCH CL may be utilized to store data externally input during the program operation, and may be referred to as data latches. When data of three bits is programmed in one memory cell MC, the data of three bits may be stored in the M-LATCH ML, the L-LATCH LL, and the C-LATCH CL, respectively. Until a program of the memory cell MC is completed, the M-LATCH ML, the L-LATCH LL, and the C-LATCH CL may maintain the stored data. In addition, the C-LATCH CL may receive data read from a memory cell MC during the read operation from the S-LATCH SL, and output the received data to the outside via the data input/output line.

In addition, the main unit MU may further include first through fourth transistors NM1 through NM4. The first transistor NM1 may be connected between the sensing node SO and the S-LATCH SL, and may be driven by a ground control signal SOGND. The second transistor NM2 may be connected between the sensing node SO and the F-LATCH FL, and may be driven by a forcing monitoring signal MON_F. The third transistor NM3 may be connected between the sensing node SO and the M-LATCH ML, and may be driven by a higher bit monitoring signal MON_M. The fourth transistor NM4 may be connected between the sensing node SO and the L-LATCH LL, and may be driven by a lower bit monitoring signal MON_L.

In addition, the main unit MU may further include fifth and sixth transistors NM5 and NM6 connected to each other in series between the bit-line selection transistor TV_hv and the sensing node SO. The fifth transistor NM5 may be driven by a bit-line shut-off signal BLSHF, and the sixth transistor NM6 may be driven by a bit-line connection control signal CLBLK. In addition, the main unit MU may further include a precharge transistor PM. The precharge transistor PM may be connected to the sensing node SO, driven by a load signal LOAD, and precharge the sensing node SO to a precharge level in a precharge period.

In an example embodiment, the main unit MU may further include a pair of pass transistors connected to the sensing node SO, or first and second pass transistors TR and TR'. According to an example embodiment, the first and second pass transistors TR and TR′ may also be referred to as first and second sensing node connection transistors, respectively. The first and second pass transistors TR and TR′ may be driven in response to a pass control signal SO_PASS. According to an example embodiment, the pass control signal SO_PASS may be referred to as a sensing node connection control signal. The first pass transistor TR may be connected between a first terminal SOC_U and the sensing node SO, and the second pass transistor TR′ may be between the sensing node SO and a second terminal SOC_D.

For example, when the page buffer unit PBU corresponds to the second page buffer unit PBU2 in FIG. 13, the first terminal SOC_U may be connected to one end of the pass transistor included in the first page buffer unit PBU1, and the second terminal SOC_D may be connected to one end of the pass transistor included in the third page buffer unit PBU3. In this manner, the sensing node SO may be electrically connected to the combined sensing node SOC via pass transistors included in each of the third through m-th page buffer units PBU3 through PBUM.

During the program operation, the page buffer PB may verify whether the programming is completed in a memory cell MC selected among the memory cells MC included in the NAND string connected to the bit-line BL. The page buffer PB may store data sensed via the bit-line BL during the program verify operation in the S-LATCH SL. The M-LATCH ML and the L-LATCH LL may be set in which target data is stored according to the sensed data stored in the S-LATCH SL.

For example, when the sensed data indicates that the programming is completed, the M-LATCH ML and the L-LATCH LL may be switched to a program inhibit setup for the selected memory cell MC in a subsequent program loop. The C-LATCH CL may temporarily store input data provided from the outside. During the program operation, the target data to be stored in the C-LATCH CL may be stored in the M-LATCH ML and the L-LATCH LL.

Hereinafter, assuming that signals for controlling elements in the page buffer circuit 410 are included in the control signal PCTL in FIG. 9.

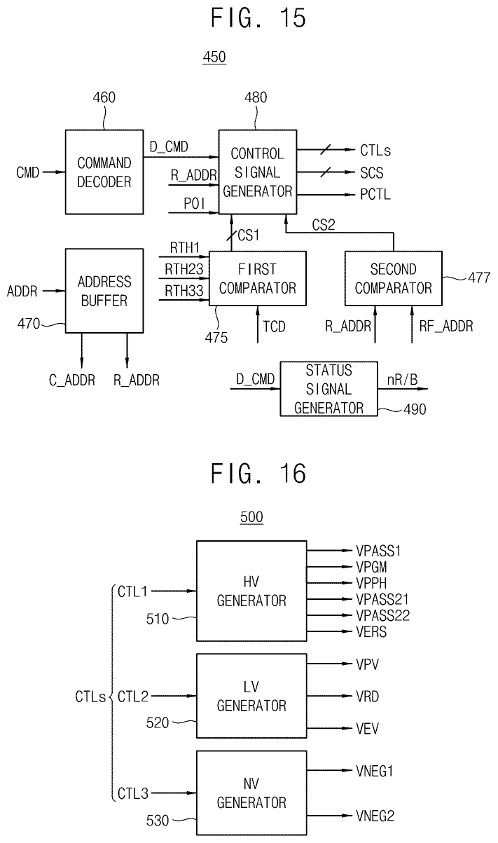

FIG. 15 is a block diagram illustrating the control circuit in the nonvolatile memory device of FIG. 9 according to example embodiments.

Referring to FIG. 15, the control circuit 450 may include a command decoder 460, an address buffer 470, a first comparator 475, a second comparator 477, a control signal generator 480 and a status signal generator 490.

The command decoder 460 may decode the command CMD and may provide a decoded command D_CMD to the control signal generator 480.

The address buffer 470 may receive the address (signal) ADDR, provide the row address R_ADDR to the address decoder 600 and the second comparator 477 and provide the column address C_ADDR to the data I/O circuit 420.

The first comparator 475 may compare the digital temperature code TCD with a first reference temperature RTH1, a second reference temperature RTH2 and a third reference temperature RTH2 and may provide the control signal generator 480 with a first comparison signal CS1 indicating a result of the comparison. The first comparison signal CS1 may include a plurality of bits, may indicate whether the digital temperature code TCD is greater than the first reference temperature RTH1, may indicate whether the digital temperature code TCD is greater than the second reference temperature RTH2 and may indicate whether the digital temperature code TCD is greater than the third reference temperature RTH3. That is, the first comparison signal CS1 may indicate which temperature range the digital temperature code TCD corresponds to (i.e., which temperature range includes the digital temperature code TCD).

The second comparator may compare the row address R_ADDR with a reference (row) address and may provide the control signal generator 480 with a second comparison signal CS2 indicating whether the row address RA_ADDR is lower or higher than the reference address RF_ADDR. That is, the second comparison signal CS2 indicating whether the selected word-line is located above a reference word-line designated by the reference address RF_ADDR or located below the reference word-line.

The control signal generator 480 may receive the decoded command D_CMD, the first comparison signal CS1 and the second comparison signal CS2, based on at least one of an operation directed by the decoded command D_CMD the first comparison signal CS1 and the second comparison signal CS2, generate the control signals CTLs, provide the control signals CTLs to the voltage generator 500, generate the control signal PCTL, provide the control signal PCTL to the page buffer circuit 410, generate the switching control signal SCS and provide switching control signal SCS to the address decoder 600. The control circuit 450 may receive a program order information POI and may generate the control signals CTLs and the switching control signal SCS. The program order information POI may indicate whether a program order of the program operation is associated with a first program order or a second program order. According to some example embodiments, the program operation may be sequentially performed from an uppermost word-line to a lowermost word-line with respect to the substrate, among a plurality word-lines coupled to the plurality of memory cells according to the first program order. According to some example embodiments, the program operation may be sequentially performed from the lowermost word-line to the upper word-line with respect to the substrate, among the plurality word-lines coupled to the plurality of memory cells according to the second program order.

When the decoded command D_CMD designates a program operation, the control signal generator 480 may generate the switching control signal SCS based on the first comparison signal CS1 and the second comparison signal CS2. The control circuit 450 may determine a first zone of unselected word-lines to which the first verification pass voltage is applied and a second zone of unselected word-lines to which the second verification pass voltage is applied by using the switching control signal SCS.

Hereinafter, assuming that the second comparison signal CS2 indicates that the row address R_ADDR is lower than the reference address RF_ADDR and the program order information POI indicates that the program order corresponds to the first program order.

When the decoded command D_CMD designates the program operation when the first comparison signal CS1 indicates that the sensed operating temperature indicated by the digital temperature code TCD is equal to or greater than the first reference temperature RTH1, (e.g., when the first comparison signal CS1 indicates that the sensed operating temperature is in the first temperature range), the control signal generator 480 may generate the control signals CTLs and the switching control signal SCS such that the second verification voltage is applied to the second zone of the unselected word-lines corresponding to the second number having a default value.

When the decoded command D_CMD designates the program operation when the first comparison signal CS1 indicates that the sensed operating temperature indicated by the digital temperature code TCD is between the first reference temperature RTH1 and the second reference temperature RTH2, (e.g., when the first comparison signal CS1 indicates that the sensed operating temperature is in the second temperature range), the control signal generator 480 may generate the control signals CTLs and the switching control signal SCS such that the second verification voltage is applied to the second zone of the unselected word-lines corresponding to the second number having a first value less than the default value.

When the decoded command D_CMD designates the program operation when the first comparison signal CS1 indicates that the sensed operating temperature indicated by the digital temperature code TCD is between the second reference temperature RTH2 and the third reference temperature RTH3, (e.g., when the first comparison signal CS1 indicates that the sensed operating temperature is in the third temperature range), the control signal generator 480 may generate the control signals CTLs and the switching control signal SCS such that the second verification voltage is applied to the second zone of the unselected word-lines corresponding to the second number having a second value less than the first value.

When the decoded command D_CMD designates the program operation when the first comparison signal CS1 indicates that the sensed operating temperature indicated by the digital temperature code TCD is lower than the third reference temperature RTH3, (e.g., when the first comparison signal CS1 indicates that the sensed operating temperature is in the fourth temperature range), the control signal generator 480 may generate the control signals CTLs and the switching control signal SCS such that the second verification voltage is applied to the second zone of the unselected word-lines corresponding to the second number having a third value less than the second value.

Therefore, the control circuit 450 may adjust the first number in the first zone of the unselected word-lines to which the first verification pass voltage is applied and the second number in the second zone of the unselected word-lines to which the second verification pass voltage is applied, based on operating temperature of the nonvolatile memory device 100 and may prevent the sensed current from being degraded as the operating temperature decreases by increasing the first number while decreasing the second number as the operating temperature decreases.

FIG. 16 is a block diagram illustrating the voltage generator in the nonvolatile memory device of FIG. 9 according to example embodiments.

Referring to FIG. 16, the voltage generator 500 may include a high voltage HV generator 510 and a low voltage LV generator 520. The voltage generator 500 may further include a negative voltage NV generator 530.

The high voltage generator 510 may generate a program voltage VPGM, a high voltage VPPH, a pass voltage PPASS, a first verification pass voltage VPASS21, a second verification pass voltage VPASS22 and an erase voltage VERS according to operations directed by the command CMD, in response to a first control signal CTL1. The pass voltage VPAS1S may include a program pass voltage and a read pass voltage.

The program voltage VPGM may be applied to the selected word-line, the pass voltage VPASS1 may be applied to the unselected word-lines during the program execution period and during the read operation, the first verification pass voltage VPASS21 may be applied to the first zone of the unselected word-line in the program verification operation, the second verification pass voltage VPASS22 may be applied to the second zone of the unselected word-line in the program verification operation, and the erase voltage VERS may be applied to a channel of the cell string. The high voltage VPPH may be applied to a gate of each of pass transistors coupled to word-lines, a string selection line and a ground selection line. The first control signal CTL1 may include a plurality of bits which indicate the operations directed by the decoded command D_CMD.

The low voltage generator 520 may generate a program verification voltage VPV, an erase verification voltage VEV and a read voltage VRD according to operations directed by the command CMD, in response to a second control signal CTL2.

The program verification voltage VPV, the read voltage VRD, and the erase verification voltage VEV may be applied to the word-lines of the target memory block. The second control signal CTL2 may include a plurality of bits which indicate the operations directed by the decode command d_cmd.

The negative voltage generator 530 may generate a first negative voltage VNEG1 and a second negative voltage VNEG2 which have negative levels according to operations directed by the command CMD, in response to a third control signal CTL3. The third control signal CTL3 may include a plurality of bits which indicate the operations directed by the decoded command D_CMD. The first negative voltage VNEG1 and the second negative voltage VNEG2 may be used for the program operation.

The control circuit 450 in FIG. 9 may receive the program command, the program data and the access address and may control the voltage generator 500 and the address decoder 600 to control the program operation by applying the program voltage VPGM to the selected word-line in the program execution period by applying the first verification pass voltage VPASS21 to the first zone of the unselected word-lines and by applying the second verification pass voltage VPASS22 to the second zone of the unselected word-lines during the program verification period, based on the sensed operating temperature.

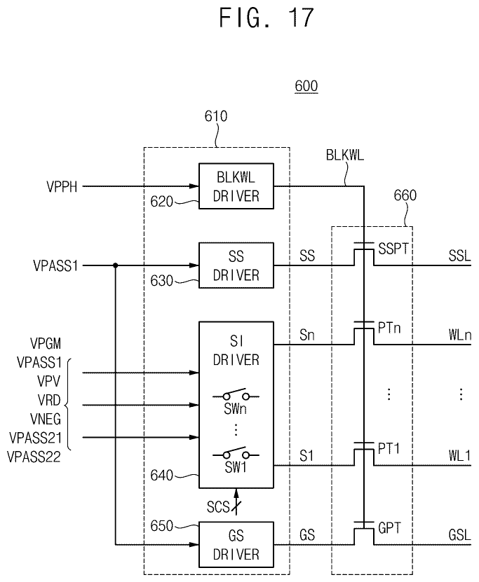

FIG. 17 is a block diagram illustrating an example of the address decoder in the nonvolatile memory device of FIG. 9 according to example embodiments.

Referring to FIG. 17, the address decoder 600 may include a driver circuit 610 and a pass transistor circuit 660.

The driver circuit 610 may transfer voltages provided from the voltage generator 500 to the memory cell array 200 in response to a block address. The driver circuit 610 may include a block selection driver BWLWL DRIVER 620, a string selectin driver SS DRIVER 630, a driving line driver SI DRIVER 640 and a ground selection driver GS DRIVER 650.

The block selection driver 620 may supply the high voltage VPPH from the voltage generator 500 to the pass transistor circuit 660 in response to the block address. The block selection driver 620 may supply the high voltage VPPH to a block word-line BLKWL coupled to gates of a plurality of pass transistors GPT, PT1˜PTn and SSPT in the pass transistor circuit 660. The block selection driver 620 may control the application of various voltages such as a pass voltage, a program voltage, a read voltage to the memory cell array 200.

The string selection driver 630 may supply voltage (for example, pass voltage VPASS) from the voltage generator 500 to the string selection line SSL through the pass transistor SSPT as a string selection signal SS. During the program operation, the string selection driver 630 may supply the selection signal SS so as to turn on all string selection transistors in a selected memory block.

The driving line driver 640 may supply the program voltage VPGM, the pass voltage VPASS1, the verification voltage VPV, the read voltage VRD, a negative voltage VNEG, the first verification voltage VPASS21 and the second verification voltage VPASS22 from the voltage generator 500 to the word-lines WL1˜WLn through driving lines S1˜Sn and the pass transistors PT1˜PTn.

The driving line driver 640 may include a plurality of switches SW1˜SWn that transfer a portion of the program voltage VPGM, the pass voltage VPASS1, the verification voltage VPV, the read voltage VRD, the negative voltage VNEG, the first verification voltage VPASS21 and the second verification voltage VPASS22 to the driving lines S1˜Sn in response to the switching control signal SCS.

The ground selection driver 650 may supply voltage (for example, pass voltage VPASS1) from the voltage generator 500 to the ground selection line GSL through the pass transistor GPT as a ground selection signal GS.

The pass transistors GPT, PT1˜PTn and SSPT are configured such that the ground selection line GSL, the word-lines WL1˜WLn and the string selection line SSL are electrically connected to corresponding driving lines, in response to activation of the high voltage VPPH on the block word-line BLKWL. In example embodiments, each of the pass transistors GPT, PT1˜PTn, SSPT CPT may include a high voltage transistor capable of enduring high-voltage.

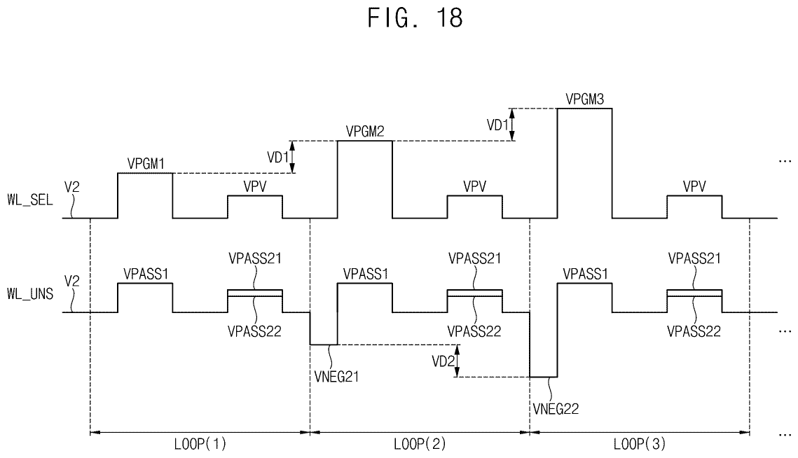

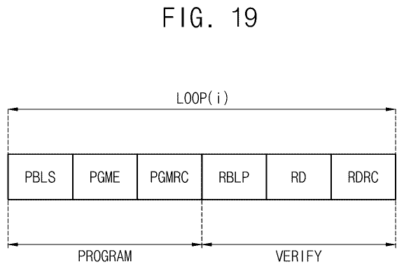

FIG. 18 is a diagram a plurality of program loops for an incremental step pulse programming (ISPP), and FIG. 19 is a diagram illustrating operation periods included in each of the program loops in FIG. 18.

Referring to FIGS. 18 and 19, a plurality of program loops LOOP(1), LOOP(2) and LOOP(3) are performed sequentially according to ISPP until the program operation is completed. As the program loops are repeated, the program voltages VPGM1, VPGM2 and VPGM3 may be increased step-wisely. The program voltages VPGM1, VPGM2 and VPGM3 may be increased step-wisely by a first voltage difference (i.e., a gap) VD1 as a number of the program loops increases. In addition, as the program loops are repeated, second negative voltages VNEG21 and VNEG22 applied to the unselected word-line during the bit-line set-up period may be decreased step-wisely. The second negative voltages VNEG21 and VNEG22 may be decreased step-wisely by a second voltage difference (i.e., a gap) VD2 as a number of the program loops increases.

Each program loop LOO(i) may include a program period PROGRAM to apply each of the program voltages VPGM1, VPGM2 and VPGM3 to a selected word-line for programming the selected memory cells and a program verification period VERIFY to apply a verification read voltage VPV to the selected word-line for verifying the success of the program operation.

The program period PROGRAM may include the bit-line set-up period PBLS, a program execution period PGME and a program recovery period PGMRC. The program verification period VERIFY may include a bit-line precharge period PBLP, a verification read period VFRD and a read recovery period RDRC. The bit-line set-up period PBLS, the program execution period PGME, the program recovery period PGMRC and the verification read period VFRD are the same as described with reference to FIG. 5.

During the bit-line set-up period PBLS of the first program loop LOOP(1), the channel of each of the cell strings is precharged to a first voltage by applying the second voltage V2 to the selected word-line and the unselected word-lines. During the bit-line set-up period PBLS of each of the program loops LOOP(2) and LOOP(3) except the first program loop LOOP(1), the second voltage V2 is applied to the selected word-line while the second negative voltages VNEG21 and VNEG22, which are decreased step-wisely the number of the program loops increases, are applied to the unselected word-lines. In addition, the program pass voltage VPASS1 is applied to the selected word-line in each of the program loops LOOP(1), LOOP(2) and LOOP(3).

In this case, a difference between the negative voltage applied to the unselected word-line during the bit-line set-up period and a program pass voltage VPASS1 applied to the unselected word-line during the program execution period is increased as the number of the program loops increases. As such, a booting effect may be obtained, which is the same in case when a fixed voltage applied to the unselected word-line during the bit-line set-up period and the program pass voltage VPPASS applied to the unselected word-line during the program execution period is increased step-wisely as the number of the program loops increases. In addition, a program disturb which occurs in the unselected cell string due to a difference between the program voltage and the program pass voltage may be the same in case when fixed voltage applied to the unselected word-line during the bit-line set-up period and the program pass voltage VPPASS applied to the unselected word-line during the program execution period is increased step-wisely as the number of the program loops increases. In addition, a pass disturbance which occurs due to a level of the program pass voltage applied to the unselected word-lines of the selected cell string may decrease because the program pass voltage is fixed.

In addition, while the first verification pass voltage VPASS21 and the second verification pass voltage VPASS22 are applied to the unselected word-lines during the program verification operation of each of the program loops LOOP(1), LOOP(2) and LOOP(3), the second number in the second zone of the unselected word-lines may be adjusted based on the operating temperature.

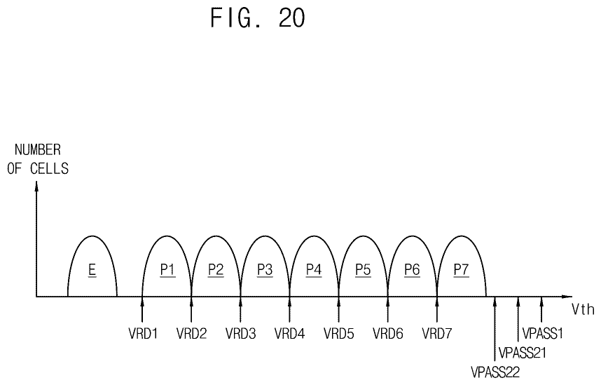

FIG. 20 is a graph showing a threshold voltage distributions of memory cells in FIG. 12.

In FIG. 20, a horizontal axis represents a threshold voltage Vth and the vertical axis represents the number of memory cells.

Below, it is assumed that each of the memory cells of the nonvolatile memory device 100 is a triple level cell (TLC) configured to store 3-bit data. However, example embodiments are not limited thereto. For example, each memory cell may be a single level cell (SLC) storing 1-bit data, or a multi-level cell (MLC), a triple level cell (TLC), a quad level cell (QLC) or a penta level cell (PLC) storing q-bit data (q being a natural number greater than 1).

Referring to FIGS. 12 and 20, each memory cell may be programmed to have one of an erase state “E” and first to seventh program states P1, P2, P3, P4, P5, P6 and P7. To read data programmed in the memory cells, the nonvolatile memory device 100 may use a plurality of read voltages VRD1, VRD2, VRD3, VRD4, VRD5, VRD6 and VRD7 and a read pass voltage VPASS1. For example, to read data programmed in memory cells connected with a selected word-line, the nonvolatile memory device 100 may sequentially apply the plurality read voltages VRD1, VRD2, VRD3, VRD4, VRD5, VRD6 and VRD7 to the selected word-line and may apply the read pass voltages VPASS to the unselected word-lines. A voltage level of the read pass voltages VPASS1 may be greater than voltage levels of the read voltages VRD1, VRD2, VRD3, VRD4, VRD5, VRD6 and VRD7.

During the program verification operation, the first verification pass voltage VPASS21 and the second verification pass voltage VPASS22 are applied to the unselected word-lines. A voltage level of the first verification pass voltage VPASS21 may be greater than a level of the second verification pass voltage VPASS22.

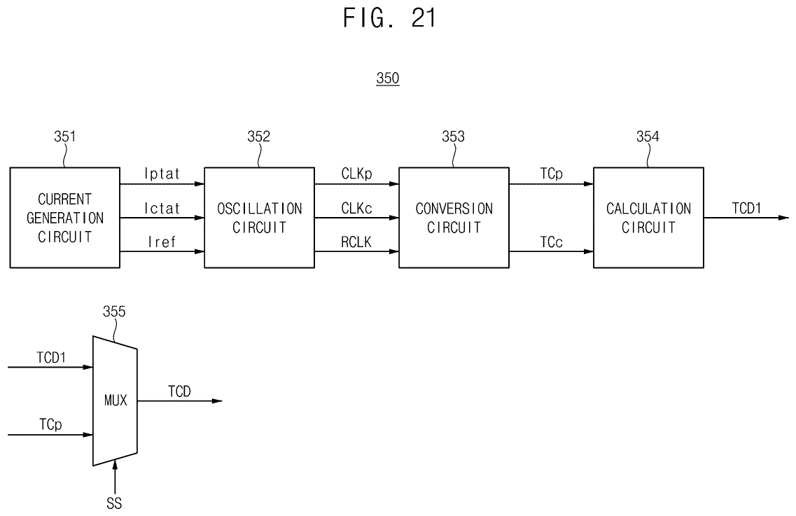

FIG. 21 is a block diagram illustrating an example of a digital temperature sensor in the nonvolatile memory device of FIG. 9 according to example embodiments.

Referring to FIG. 21, the digital temperature sensor 350 may include a current generation circuit 351, an oscillation circuit 352 a conversion circuit 353, a calculation circuit 354 and a multiplexer 355.

The current generation circuit 351 may generate a proportional to absolute temperature (PTAT) current Iptat that is proportional to the operating temperature and may generate a complementary to absolute temperature CTAT current Ictat that is inversely proportional to the operating temperature.

In example embodiments, the current generation circuit 351 may be implemented with a bandgap reference circuit configured to generate, in addition to the PTAT current Iptat and the CTAT current Ictat, a reference current Iref that is fixed regardless of the operating temperature.

The oscillation circuit 352 may generate a first clock signal CLKp having a first cyclic period based on the PTAT current Iptat such that the first cyclic period may be inversely proportional to the PTAT current Iptat. In addition, the oscillation circuit 352 may generate a second clock signal CLKc having a second cyclic period based on the CTAT current Ictat such that the second cyclic period may be inversely proportional to the CTAT current Ictat. In example embodiments, the oscillation circuit 352 may further generate, in addition to the first clock signal CLKp and the second clock signal CLKc, a reference clock signal RCLK having a reference cyclic period that is fixed regardless of the operating temperature based on the reference current Iref.

The conversion circuit 353 may generate a first temperature code TCp based on the first clock signal CLKp such that the first temperature code TCP may decrease as the operating temperature increases. In addition, the conversion circuit 353 may generate a second temperature code TCc based on the second clock signal CLKc such that the second temperature code TCc may increase as the operating temperature increases.

The calculation circuit 354 may generate a first digital temperature code TCD1 by calculating a difference between the first temperature code TCp and the second temperature code TCc. The calculation circuit 354 may generate the first digital temperature code TCD1 by subtracting the second temperature code TCc from the first temperature code TCp such that the corrected temperature code TC may decrease as the operating temperature decreases.

The multiplexer 355, in response to a selection signal SS, may select one of the first digital temperature code TCD1 and the first temperature code TCp as the digital temperature code TCD.

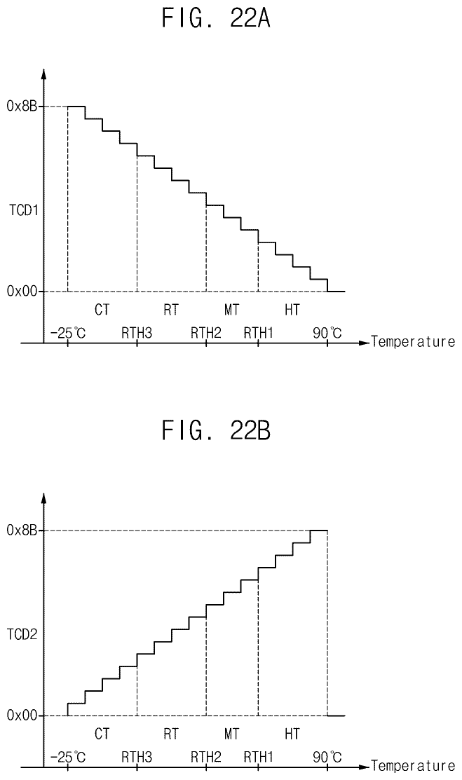

FIG. 22A illustrates a digital temperature code based on the operating temperature.

Referring to FIG. 22A, the plurality of temperature ranges may include a first temperature range HT equal to or greater than the first reference temperature RTH1, a second temperature range MT between the first reference temperature RTH1 and the second reference temperature RTH2, a third temperature range RT between second reference temperature RTH2 and the third reference temperature RTH3, and a fourth temperature range CT equal to or less than the third reference temperature RTH3. The digital temperature sensor 350 of FIG. 21 may output the first digital temperature code TCD1 which decreases from 0x8B to 0x0B as the operating temperature increases.

The control circuit 450, based on the first digital temperature code TCD1, may control the program operation such that the second number in the second zone of the unselected word-line to which the second verification voltage VPASS22 is decreased as the operating temperature decreases in the program verification operation.

FIG. 22B illustrates a digital temperature code based on the operating temperature.

Referring to FIG. 22B, the plurality of temperature ranges may include a first temperature range HT equal to or greater than the first reference temperature RTH1, a second temperature range MT between the first reference temperature RTH1 and the second reference temperature RTH2, a third temperature range RT between second reference temperature RTH2 and the third reference temperature RTH3, and a fourth temperature range CT equal to or less than the third reference temperature RTH3. The digital temperature sensor 350 of FIG. 21 may output a second digital temperature code TCD2 which increases from 0x0B to 0x8B as the operating temperature increases.

The control circuit 450, based on the second digital temperature code TCD2, may control the program operation such that the second number in the second zone of the unselected word-line to which the second verification voltage VPASS22 is decreased as the operating temperature decreases in the program verification operation.

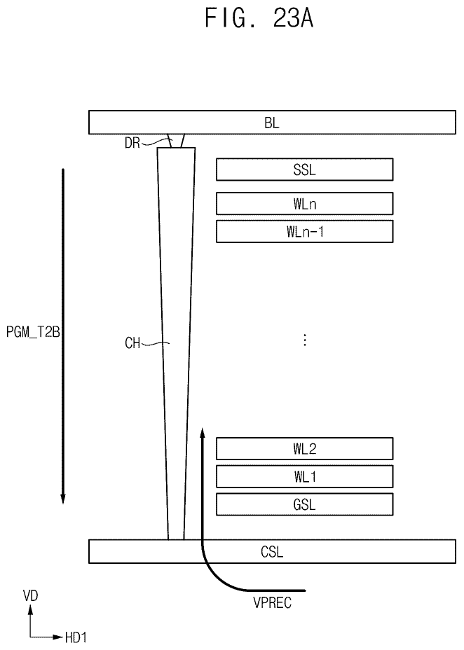

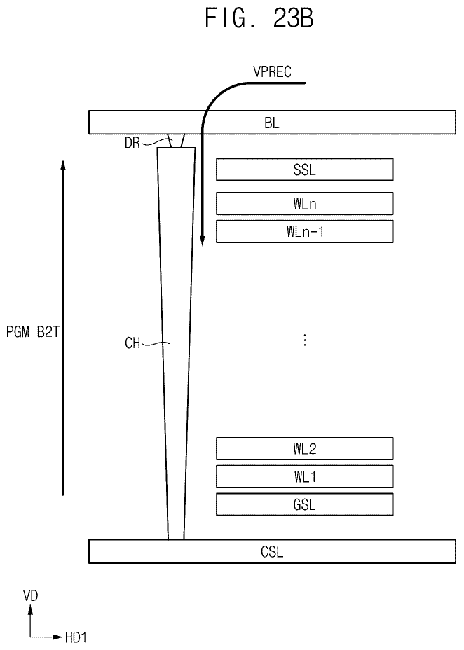

FIGS. 23A and 23B illustrate a channel and lines in a memory block, respectively.

Referring to FIGS. 23A and 23B, a structure of a plurality of lines CSL, GSL, WL1, WL2, . . . , WLn-1, WLn, SSL, BL and a channel CH included in one memory block is schematically illustrated.

The common source line CSL, the ground selection line GSL, the word-lines WL1 to WLn, the string selection line SSL and the bit-line BL may be stacked on the substrate in the vertical direction VD and may extend along the first horizontal direction HD1. The channel CH may extend along the vertical direction VD and may be connected to the bit-line BL through a drain DR.

In some example embodiments, as illustrated in FIG. 23A, the program operation may be sequentially performed from the uppermost memory cell to the lowermost memory cell. The uppermost memory cell may be connected to the uppermost word-line WLn and farthest from the substrate or the common source line CSL, and the lowermost memory cell may be connected to the lowermost word-line WL1 and closest to the substrate nor the common source line CSL. The program scheme illustrated in FIG. 23A may be referred to as a top-to-bottom (T2B) scheme, and a direction in which the program operation is performed in FIG. 23A may be ‘PGM_T2B.’ The T2B scheme may be referred to as a first program order. In this example, the initial precharge operation may be performed using a precharge voltage VPREC provided through the common source line CSL by turning on the ground selection transistor connected to the ground selection line GSL.

In some example embodiments, as illustrated in FIG. 23B, the program operation may be sequentially performed from the lowermost memory cell to the uppermost memory cell. The program scheme illustrated in FIG. 23B may be referred to as a bottom-to-top (B2T) scheme, and a direction in which the program operation is performed in FIG. 23B may be ‘PGM_B2T.’ The B2T scheme may be referred to as a second program order. In this example, the initial precharge operation may be performed using a precharge voltage VPREC provided through the bit-line BL by turning on the string selection transistor connected to the string selection line SSL.

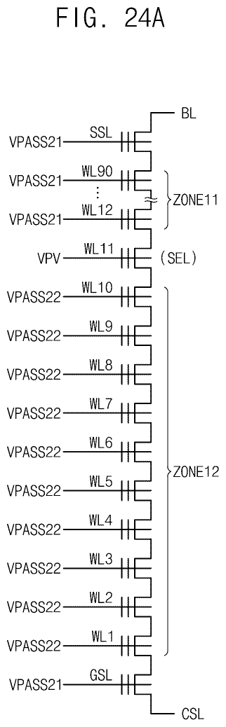

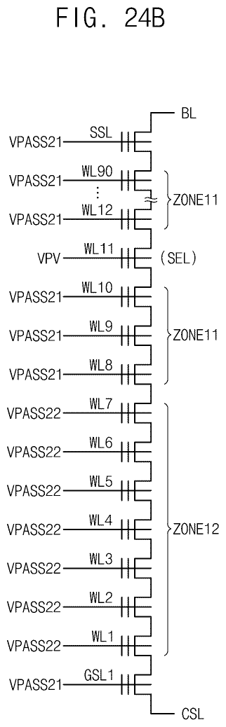

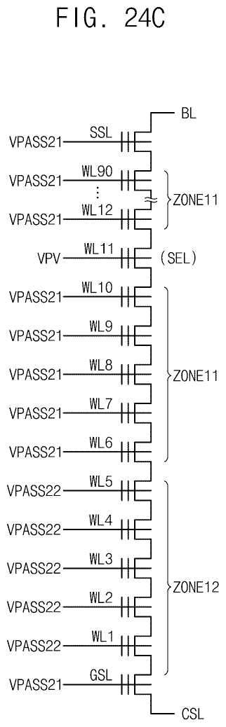

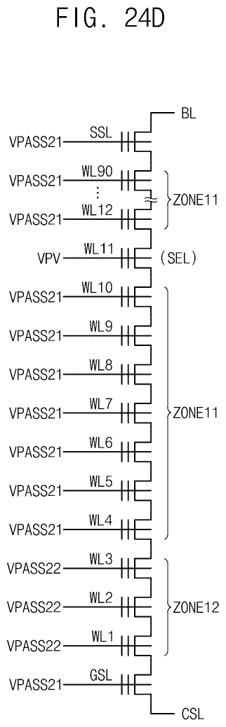

FIGS. 24A, 24B, 24C and 24D illustrate examples of adjusting the second number in the second zone of unselected word-lines based on the operating temperature according to example embodiments, respectively.

In each of FIGS. 24A, 24B, 24C and 24D, assuming that a word-line WL11 is a selected word-line among a plurality of word-lines WL1˜WL90 and the program is performed according to T2B scheme and the word-line WL12 is located above the reference word-line. A second number indicating a number of unselected word-lines provided with the second verification pass voltage may be determined based on a range including the sensed operating temperature.

Referring to FIG. 24A, when the sensed operating temperature is in the first temperature range (e.g., the hot temperature range), a second zone ZONE12 may include a second number of unselected word-lines WL1˜WL10 and a first zone ZONE11 may include a first number of unselected word-lines WL12˜WL90. The second number corresponding to the first temperature range may correspond to a default value.

During the program verification operation, the program verification voltage VPV is applied to the selected word-line WL11, the first verification pass voltage VPASS21 is applied to the string selection line SSL, the ground selection line GSL and the first number of unselected word-lines WL12˜WL90 in the first zone ZONE11 and the second verification pass voltage VPASS22 is applied to the second number of unselected word-lines WL1˜WL10 in the second zone ZONE12.

Referring to FIG. 24B, when the sensed operating temperature is in the second temperature range (e.g., the middle temperature range), a second zone ZONE12 may include a second number of unselected word-lines WL1˜WL7 and a first zone ZONE11 may include a first number of unselected word-lines WL8˜WL10 and WL12˜WL90. The second number corresponding to the second temperature range may correspond to a first value less than the default value.

During the program verification operation, the program verification voltage VPV is applied to the selected word-line WL11, the first verification pass voltage VPASS21 is applied to the string selection line SSL, the ground selection line GSL and the first number of unselected word-lines WL8˜WL10 and WL12˜WL90 in the first zone ZONE11 and the second verification pass voltage VPASS22 is applied to the second number of unselected word-lines WL1˜WL7 in the second zone ZONE12.

Referring to FIG. 24C, when the sensed operating temperature is in the third temperature range (e.g., the room temperature range), a second zone ZONE12 may include a second number of unselected word-lines WL1˜WL5 and a first zone ZONE11 may include a first number of unselected word-lines WL6˜WL10 and WL12˜WL90. The second number corresponding to the third temperature range may correspond to a second value less than the first value.

During the program verification operation, the program verification voltage VPV is applied to the selected word-line WL11, the first verification pass voltage VPASS21 is applied to the string selection line SSL, the ground selection line GSL and the first number of unselected word-lines WL6˜WL10 and WL12˜WL90 in the first zone ZONE11 and the second verification pass voltage VPASS22 is applied to the second number of unselected word-lines WL1˜WL5 in the second zone ZONE12.

Referring to FIG. 24D, when the sensed operating temperature is in the fourth temperature range (e.g., the cold temperature range), a second zone ZONE12 may include a second number of unselected word-lines WL1˜WL3 and a first zone ZONE11 may include a first number of unselected word-lines WL4˜WL10 and WL12˜WL90. The second number corresponding to the fourth temperature range may correspond to a third value less than the second value.

During the program verification operation, the program verification voltage VPV is applied to the selected word-line WL11, the first verification pass voltage VPASS21 is applied to the string selection line SSL, the ground selection line GSL and the first number of unselected word-lines WL4˜WL10 and WL12˜WL90 in the first zone ZONE11 and the second verification pass voltage VPASS22 is applied to the second number of unselected word-lines WL1˜WL3 in the second zone ZONE12.

In each of FIGS. 24A, 24B, 24C and 24D, the second zone ZONE12 may be referred to as an under zone.

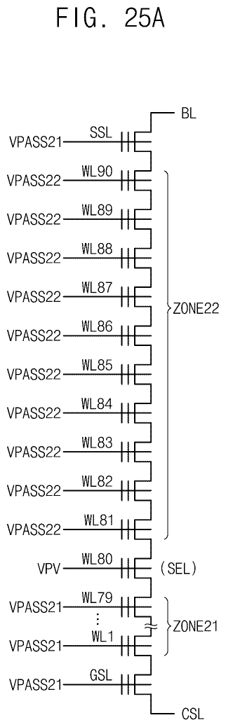

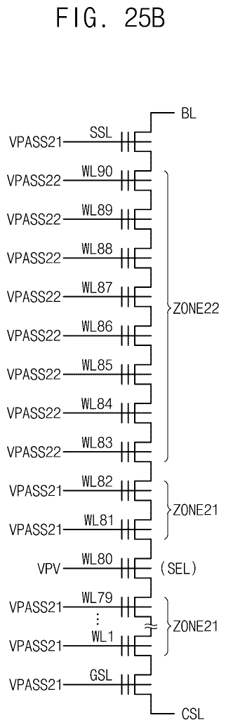

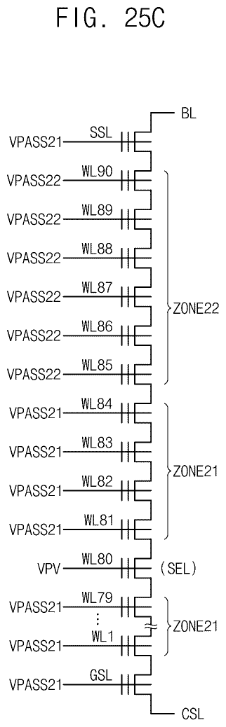

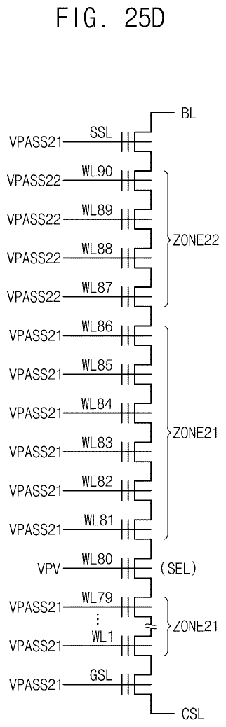

FIGS. 25A, 25B, 25C and 25D illustrate examples of adjusting the second number in the second zone of unselected word-lines based on the operating temperature according to example embodiments, respectively.

In each of FIGS. 25A, 25B, 25C and 25D, assuming that a word-line WL80 is a selected word-line among a plurality of word-lines WL1˜WL90 and the program is performed according to B2T scheme and the word-line WL80 is located below the reference word-line. A second number indicating a number of unselected word-lines provided with the second verification pass voltage may be determined based on a range including the sensed operating temperature.

Referring to FIG. 25A, when the sensed operating temperature is in the first temperature range (e.g., the hot temperature range), a second zone ZONE22 may include a second number of unselected word-lines WL81˜WL90 and a first zone ZONE21 may include a first number of unselected word-lines WL1˜WL79. The second number corresponding to the first temperature range may correspond to a default value.

During the program verification operation, the program verification voltage VPV is applied to the selected word-line WL80, the first verification pass voltage VPASS21 is applied to the string selection line SSL, the ground selection line GSL and the first number of unselected word-lines WL1˜WL79 in the first zone ZONE21 and the second verification pass voltage VPASS22 is applied to the second number of unselected word-lines WL81˜WL90 in the second zone ZONE22.

Referring to FIG. 25B, when the sensed operating temperature is in the second temperature range (e.g., the middle temperature range), a second zone ZONE22 may include a second number of unselected word-lines WL83˜WL90 and a first zone ZONE21 may include a first number of unselected word-lines WL1˜WL79 and WL81˜WL82. The second number corresponding to the second temperature range may correspond to a first value less than the default value.

During the program verification operation, the program verification voltage VPV is applied to the selected word-line WL80, the first verification pass voltage VPASS21 is applied to the string selection line SSL, the ground selection line GSL and the first number of unselected word-lines WL1˜WL79 and WL81˜WL82 in the first zone ZONE21 and the second verification pass voltage VPASS22 is applied to the second number of unselected word-lines WL83˜WL90 in the second zone ZONE22.

Referring to FIG. 25C, when the sensed operating temperature is in the second temperature range (e.g., the room temperature range), a second zone ZONE22 may include a second number of unselected word-lines WL85˜WL90 and a first zone ZONE21 may include a first number of unselected word-lines WL1˜WL79 and WL81˜WL84. The second number corresponding to the third temperature range may correspond to a second value less than the first value.

During the program verification operation, the program verification voltage VPV is applied to the selected word-line WL80, the first verification pass voltage VPASS21 is applied to the string selection line SSL, the ground selection line GSL and the first number of unselected word-lines WL1˜WL79 and WL81˜WL84 in the first zone ZONE21 and the second verification pass voltage VPASS22 is applied to the second number of unselected word-lines WL85˜WL90 in the second zone ZONE22.

Referring to FIG. 25D, when the sensed operating temperature is in the second temperature range (e.g., the cold temperature range), a second zone ZONE22 may include a second number of unselected word-lines WL87˜WL90 and a first zone ZONE21 may include a first number of unselected word-lines WL1˜WL79 and WL81˜WL86. The second number corresponding to the fourth temperature range may correspond to a third value less than the second value.

During the program verification operation, the program verification voltage VPV is applied to the selected word-line WL80, the first verification pass voltage VPASS21 is applied to the string selection line SSL, the ground selection line GSL and the first number of unselected word-lines WL1˜WL79 and WL81˜WL86 in the first zone ZONE21 and the second verification pass voltage VPASS22 is applied to the second number of unselected word-lines WL87˜WL90 in the second zone ZONE22.

In each of FIGS. 25A, 25B, 25C and 25D, the second zone ZONE22 may be referred to as an upper zone.

As a number of programming/erase cycles increases, the programming characteristics of the memory cells may degrade. Memory cell degradation reduces the amount of current flowing through the memory cells. The memory cell with the worst programming characteristics is called a ‘worst on-cell’. If a selected memory cell is the worst on-cell, current flowing through the selected memory cell is at its lowest point. Therefore, when the selected memory cells are on-cells and have degraded programming characteristics, the amount of current flowing through the memory cells are reduced. In addition, the amount of sensed current provided to the sensing node through a cell string may be reduced. However, in the nonvolatile memory device 100 according to example embodiments, the number of the unselected word-lines to which the second verification pass voltage VPASS22 is applied in the program verification operation is reduced as the operating temperature decreases, and the sensed current provided to a sensing node of a page buffer may be prevented from being degraded as the operating temperature decreases.

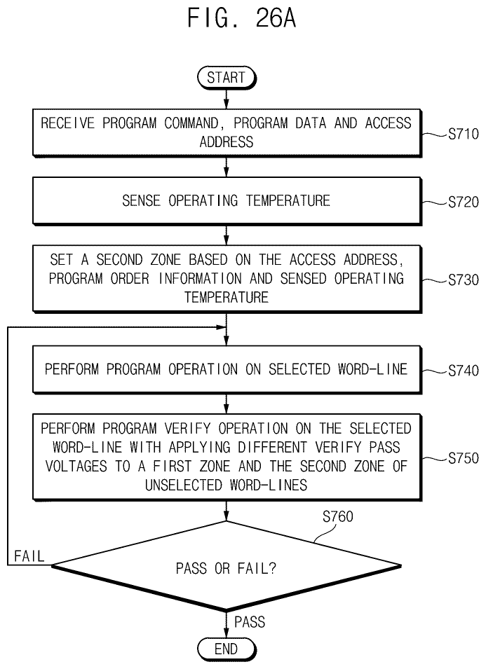

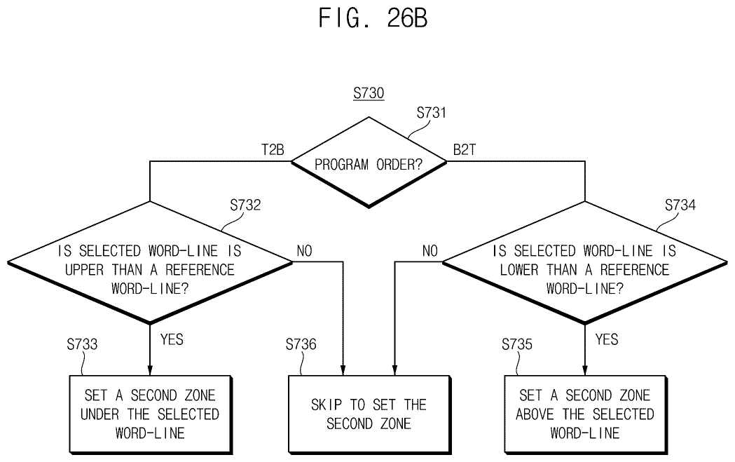

FIG. 26A is a flow chart illustrating a method of operating a nonvolatile memory device according to example embodiments.

Referring to FIGS. 5 through 26A, there is provided a method of operating a nonvolatile memory device including at least one memory block which includes a plurality of cell strings, where each cell string includes a string selection transistor, a plurality of memory cells and a ground selection transistor connected in series in a vertical direction between a bit-line and a common source line. The common source line may be formed in or on a substrate. According to the method, the nonvolatile memory device receives a program command, a program data and an access address from an external memory controller (operation S710). A temperature sensor in the nonvolatile memory device senses an operating temperature of the nonvolatile memory device while receiving the program command (operation S720).

A control circuit in the nonvolatile memory sets a second zone of unselected word-lines to which a second verification voltage is applied based on the sensed operating temperature, the access address and a program order information (operation S730).

The control circuit controls a program operation to be performed on a selected word-line of the plurality of cell strings by applying a program voltage to the selected word-line (operation S740). The control circuit controls a program verification operation by controlling a program verification voltage to be applied to the selected word-line, and a first verification pass voltage to be applied to a first zone of unselected word-lines and a second verification pass voltage to be applied to the second zone of the unselected word-lines (operation S750).

The control circuit determines pass or fail of the program operation of memory cells coupled to the selected word-line based on a result of the program verification operation (operation S760). When the memory cells are determines as a program pass (PASS in S760), the method ends. When the memory cells are determines as a program fail (FAIL in S760), the control circuit increases a voltage level of the program voltage and controls the level-increased program voltage to be applied to the selected word-line (operation S740).

FIG. 26B is a flow chart illustrating an operation of setting the second zone in the method of FIG. 26A according to example embodiments.

Referring to FIG. 26B, for setting the second zone, the control circuit determines whether a program order of the program operation is T2B or B2T based on the program order information (operation S731).

When the program order is T2B, the control circuit determines whether the selected word-line is located above a reference word-line (operation S732). When the selected word-line is located above the reference word-line (YES in S732), the control circuit sets the second zone in a lower region of unselected word-lines below the selected word-line (operation S733). When the selected word-line is not located above the reference word-line (NO in S732), the control circuit skips to set the second zone (operation S736).

When the program order is B2T, the control circuit determines whether the selected word-line is located below a reference word-line (operation S734). When the selected word-line is located below the reference word-line (YES in S734), the control circuit sets the second zone in an upper region of unselected word-lines above the selected word-line (operation S735). When the selected word-line is not located below the reference word-line (NO in S734), the control circuit skips to set the second zone (operation S736).

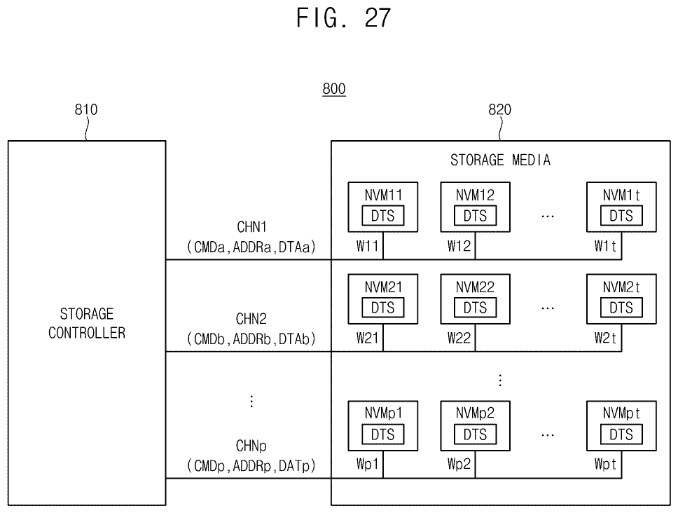

FIG. 27 is a block diagram illustrating a storage device according to example embodiments.

Referring to FIG. 27, a storage device 800 may include a storage controller 810 and a storage media 820. The storage device 800 may support a plurality of channels CHN1, CHN2, . . . , CHNp (hereinafter CHN1 to CHNp), and the storage media 820 may be connected to the storage controller 810 through the plurality of channels CHN1 to CHNp.

The storage media 820 may include a plurality of nonvolatile memory devices NVM11, NVM12, . . . , NVM1t, NVM21, NVM22, . . . , NVM2t, NVMp1, NVMp2, . . . , NVMpt. For example, the nonvolatile memory devices NVM11 to NVMpt may correspond to the nonvolatile memory device 100 of FIG. 9. Each of the nonvolatile memory devices NVM11 to NVMpt may be connected to one of the plurality of media channels CHN1 to CHNp through a way corresponding thereto. For instance, the nonvolatile memory devices NVM11 to NVM1t may be connected to the first medial channel CHN1 through ways W11, W12, . . . , W1t, the nonvolatile memory devices NVM21 to NVM2t may be connected to the second media channel CHN2 through ways W21, W22, . . . , W2t, and the nonvolatile memory devices NVMp1 to NVMpt may be connected to the p-th media channel CHNp through ways Wp1, Wp2, . . . , Wpt. In some example embodiments, each of the nonvolatile memory devices NVM11 to NVMpt may be implemented as an arbitrary memory unit that may operate according to an individual command from the storage controller 810. For example, each of the nonvolatile memory devices NVM11 to NVMpt may be implemented as a chip or a die, but example embodiments are not limited thereto.

Each of the nonvolatile memory devices NVM11 to NVMpt may include a digital temperature sensor DTS. The digital temperature sensor DTS may sense an operating temperature of a corresponding nonvolatile memory device and may provide a control circuit in the corresponding nonvolatile memory device with a digital temperature code corresponding to the sensed temperature. The control circuit may reduce the number of the unselected word-lines to which the second verification pass voltage VPASS22 is applied in the program verification operation as the operating temperature decreases, and this may prevent the sensed current provided to a sensing node of a page buffer from being degraded as the operating temperature decreases.

The storage controller 810 may transmit and receive signals to and from the storage media 820 through the plurality of media channels CHN1 to CHNp. For example, the storage controller 810 may correspond to the memory controller 50 in FIG. 8. For example, the storage controller 810 may transmit commands CMDa, CMDb, . . . , CMDp, addresses ADDRa, ADDRb, . . . , ADDRp and data DTAa, DTAb, . . . , DTAp to the storage media 820 through the media channels CHN1 to CHNp or may receive the DTAa to DTAp from the storage media 820.

The storage controller 810 may select one of the nonvolatile memories NVM11 to NVMpt, which is connected to each of the media channels CHN1 to CHNp, by using a corresponding one of the media channels CHN1 to CHNp, and may transmit and receive signals to and from the selected nonvolatile memory device.

The storage controller 810 may transmit and receive signals to and from the storage media 820 in parallel through different media channels.

The storage controller 810 may communicate with an external host according to UFS standards.

A nonvolatile memory device or a storage device according to example embodiments may be packaged using various package types or package configurations.

In some embodiments, each of the components represented by a block, such as those illustrated in FIGS. 6-9, 14A, 14B, 15-17, 21 and 27 may be implemented as various numbers of hardware and/or firmware structures that execute respective functions described above, according to example embodiments. For example, at least one of these components may include various hardware components including a digital circuit, a programmable or non-programmable logic device or array, an application specific integrated circuit (ASIC), transistors, capacitors, logic gates, or other circuitry using use a direct circuit structure, such as a memory, a processor, a logic circuit, a look-up table, etc., that may execute the respective functions through controls of one or more microprocessors or other control apparatuses. Also, at least one of these components may further include or may be implemented by a processor such as a central processing unit (CPU) that performs the respective functions, a microprocessor, or the like. Functional aspects of example embodiments may be implemented in algorithms that execute on one or more processors. Furthermore, the components, elements, modules or units represented by a block or processing steps may employ any number of related art techniques for electronics configuration, signal processing and/or control, data processing and the like.

While aspects of example embodiments have been particularly shown and described, it will be understood that various changes in form and details may be made therein without departing from the spirit and scope of the following claims.

What is claimed is:

1. A method of operating a nonvolatile memory device that includes at least one memory block, the at least one memory block including a plurality of cell strings, each of the plurality of cell strings including a string selection transistor, a plurality of memory cells and a ground selection transistor which are connected in series in a vertical direction between each of a plurality of bit-lines and a common source line in or on a substrate, the method comprising:
performing a program operation on a selected word-line of the plurality of cell strings during a program execution period of a program loop by applying a program voltage to the selected word-line; and
performing a program verification operation during a program verification period of the program loop by applying a program verification voltage to the selected word-line and by applying a first verification pass voltage to a first zone of unselected word-lines among of the plurality of cell strings and a second verification pass voltage to a second zone of the unselected word-lines,
wherein a voltage level of the second verification pass voltage is lower than a voltage level of the first verification pass voltage.

2. The method of claim 1, wherein the performing the program verification operation comprises identifying the second zone based on a position of the selected word-line along the vertical direction, and
wherein the first zone comprises a first number the of unselected word-lines and the second zone comprises a second number of the unselected word-lines.

3. The method of claim 2, further comprising:
sensing an operating temperature of the nonvolatile memory device; and
adjusting the first number and the second number based on the sensed operating temperature.

4. The method of claim 3, wherein the adjusting the first number and the second number comprises increasing the first number and reducing the second number based on a decrease in the sensed operating temperature.

5. The method of claim 3, wherein the adjusting the first number and the second number comprises setting the second number to a default value based on a first temperature range comprising the sensed operating temperature, the first temperature range being greater than a first reference temperature.

6. The method of claim 3, wherein the adjusting the first number and the second number comprises setting the second number to a first value less than a default value based on a second temperature range comprising the sensed operating temperature, the second temperature range being between a first reference temperature and a second reference temperature, and
wherein the second reference temperature is lower than the first reference temperature.

7. The method of claim 6, wherein the adjusting the first number and the second number further comprises setting the second number to a second value less than the first value based on a third temperature range comprising the sensed operating temperature, the third temperature range being between the second reference temperature and a third reference temperature, and
wherein the third reference temperature is lower than the second reference temperature.

8. The method of claim 7, wherein the adjusting the first number and the second number further comprises:
setting the second number to a third value less than the second value based on the sensed operating temperature being in a fourth temperature range equal to or lower than the third reference temperature; and
applying the first verification pass voltage and the second verification pass voltage to the unselected word-lines based on the first number and the second number.

9. The method of claim 2, further comprising:
determining whether a program order of the program operation is associated with a first program order or a second program order; and
setting the second zone in a lower region of the selected word-line or an upper region of the selected word-line based on the program order,
wherein the program operation is sequentially performed from an uppermost word-line to a lowermost word-line with respect to the substrate, among a plurality word-lines coupled to the plurality of memory cells according to the first program order, and
wherein the program operation is sequentially performed from the lowermost word-line to the uppermost word-line with respect to the substrate, among the plurality word-lines coupled to the plurality of memory cells according to the second program order.

10. The method of claim 9, further comprising:
determining whether the selected word-line is located above a reference word-line along the vertical direction based on the program operation being performed according to the first program order; and
setting the second zone in the lower region based on the selected word-line being located above the reference word-line along the vertical direction.

11. The method of claim 9, further comprising:
determining whether the selected word-line is located below a reference word-line along the vertical direction based on the program operation being performed according to the second program order; and
setting the second zone in the upper region based on the selected word-line being located below the reference word-line along the vertical direction.

12. The method of claim 2, wherein the sensed operating temperature is provided as a digital temperature code, and a value of the digital temperature code is proportional or inversely proportional to the sensed operating temperature, and
wherein the method further comprises increasing the first number and reducing the second number based on the digital temperature code indicating a decrease in the sensed operating temperature.

13. A nonvolatile memory device comprising:
a memory cell array comprising at least one memory block, the at least one memory block including a plurality of cell strings, each of the plurality of cell strings comprising a string selection transistor, a plurality of memory cells and a ground selection transistor which are connected in series in a vertical direction between each of a plurality of bit-lines and a common source line in or on a substrate;
a temperature sensor configured to sense an operating temperature of the nonvolatile memory device; and
a control circuit configured to, based on a program command and an access address:
perform a program operation on a selected word-line of the plurality of cell strings during a program execution period of a program loop by applying a program voltage to the selected word-line; and
perform a program verification operation during a program verification period of the program loop by applying a program verification voltage to the selected word-line and by applying a first verification pass voltage to a first zone of unselected word-lines among of the plurality of cell strings and a second verification pass voltage to a second zone of the unselected word-lines,
wherein a voltage level of the second verification pass voltage is lower than a voltage level of the first verification pass voltage.

14. The nonvolatile memory device of claim 13, further comprising:
a voltage generator configured to generate, based on control signals, word-line voltages comprising the program voltage, the program verification voltage, the first verification pass voltage and the second verification pass voltage; and
an address decoder configured to provide the word-line voltages to the at least one memory block based on a row address corresponding to the access address.

15. The nonvolatile memory device of claim 14, wherein the control circuit is further configured to:
identify the second zone based on a position of the selected word-line along the vertical direction; and
control the voltage generator and the address decoder to apply the first verification pass voltage to the first zone based on a position of the selected word-line along the vertical direction, and
wherein the first zone comprises a first number of the unselected word-lines and the second zone comprises a second number of the unselected word-lines.

16. The nonvolatile memory device of claim 15, wherein the control circuit is further configured to increase the first number and reduce the second number based on a decrease in the sensed operating temperature during the program verification operation.

17. The nonvolatile memory device of claim 15, wherein the control circuit is further configured to adjust the first number and the second number differently based on which of a plurality of temperature ranges comprises the sensed operating temperature.

18. The nonvolatile memory device of claim 14, wherein the control circuit is further configured to:
determine whether a program order of the program operation is associated with a first program order or a second program order; and
set the second zone in a lower region of the selected word-line or an upper region of the selected word-line based on the program order,
wherein the program operation is initially performed on an uppermost word-line from the substrate, among a plurality word-lines coupled to the plurality of memory cells according to the first program order, and
wherein the program operation is initially performed on a lowermost word-line from the substrate among the plurality word-lines coupled to the plurality of memory cells according to the second program order.

19. The nonvolatile memory device of claim 13, wherein the first zone comprises a first number of the unselected word-lines and the second zone comprises a second number of the unselected word-lines,
wherein the temperature sensor is configured to provide the sensed operating temperature as a digital temperature code,
wherein a value of the digital temperature code is proportional or inversely proportional to the operating temperature, and
wherein the control circuit is further configured to increase the first number and reduce the second number based on the digital temperature code indicating a decrease in the sensed operating temperature.

20. A nonvolatile memory device comprising:
a memory cell array comprising at least one memory block, the at least one memory block including a plurality of cell strings, each of the plurality of cell strings comprising a string selection transistor, a plurality of memory cells and a ground selection transistor which are connected in series in a vertical direction between a first bit-line and a common source line in or on a substrate;
a page buffer coupled to the memory cell array through the first bit-line;
a digital temperature sensor configured to generate a digital temperature code corresponding to an operating temperature of the nonvolatile memory device; and
a control circuit configured to, based on a program command and an access address:
perform a program operation on a selected word-line of the plurality of cell strings during a program execution period of a program loop by applying a program voltage to the selected word-line;
perform a program verification operation during a program verification period of the program loop by applying a program verification voltage to the selected word-line and by applying a first verification pass voltage to a first zone of unselected word-lines among of the plurality of cell strings and a second verification pass voltage to a second zone of the unselected word-lines; and
increase the first number and reducing the second number based on the digital temperature code indicating a decrease in the sensed operating temperature during the program verification operation to perform temperature compensation on a current provided to a sensing node of the page buffer through the first bit-line, the first zone comprising a first number of the unselected word-lines and the second zone comprising a second number of the unselected word-lines, and
wherein a voltage level of the second verification pass voltage is lower than a voltage level of the first verification pass voltage.
